(19) United States
(12) Patent Application Publication
(10) Pub. No.: US 2025/0285689 A1
(43) Pub. Date: Sep. 11, 2025

(54) NON-VOLATILE MEMORY DEVICE AND METHOD OF OPERATING THE NON-VOLATILE MEMORY DEVICE

(71) Applicant: Samsung Electronics Co., Ltd., Suwon-si (KR)

(72) Inventors: Seungyong Choi, Suwon-si (KR); Yonghyuk Choi, Suwon-si (KR); Se-Heon Baek, Suwon-si (KR)

(21) Appl. No.: 18/952,328

(22) Filed: Nov. 19, 2024

(30) Foreign Application Priority Data
Mar. 8, 2024 (KR) 10-2024-0033134

(51) Int. Cl. G11C 16/34; G11C 16/24

(52) U.S. Cl. CPC G11C 16/3459; G11C 16/24

(57) ABSTRACT

A non-volatile memory device includes a memory cell array including a first memory cell connected to a first bit line and having a first program status, a second memory cell connected to a second bit line that is different from the first bit line and having a second program status that is a higher level status than the first program status, and a third memory cell connected to a third bit line that is different from the first and second bit lines and having a third program status that is a higher level status than the first and second program status and a page buffer configured to apply a pre-charge voltage to the first and second bit lines in a first verify operation for the second program status, and apply the pre-charge voltage to the third bit line in a second verify operation for the third program status.

### CROSS-REFERENCE TO RELATED APPLICATION

This application claims priority to and the benefit of Korean Patent Application No. 10-2024-0033134 filed on Mar. 8, 2024, the entire contents of which are incorporated herein by reference.

### BACKGROUND OF THE INVENTION

### (a) Field of the Invention

The disclosure relates to a non-volatile memory device and a method of operating the non-volatile memory device.

### (b) Description of the Related Art

A non-volatile memory device stores data through a program operation and preserves the stored data even when power is turned off. The program operation of the non-volatile memory may include an operation of providing a program voltage pulse to a memory cell, and a verify operation that verifies the program status of the memory cell by providing a pre-charge voltage through a bit line after providing the program voltage pulse to the memory cells.

The verify operation may be performed through several types of pre-charge voltage provision technologies, and each pre-charge voltage provision technology has different characteristics in terms of performance or power-efficiency.

### SUMMARY OF THE INVENTION

An embodiment provides a non-volatile memory device and an operation method thereof that improves power-efficiency of a program operation.

An embodiment provides a non-volatile memory device and an operation method thereof that improves the operation performance of the program operation.

According to the disclosed embodiment, a non-volatile memory device including a memory cell array including a first memory cell connected to a first bit line and having a first program status, a second memory cell connected to a second bit line that is different from the first bit line and having a second program status that is a higher level status than the first program status, and a third memory cell connected to a third bit line that is different from the first and second bit lines and having a third program status that is a higher level status than the first program status and the second program status, and a page buffer configured to apply a pre-charge voltage to the first and second bit lines in a first verify operation for the second program status, and apply the pre-charge voltage to the third bit line in a second verify operation for the third program status is provided.

According to the disclosed embodiment, a non-volatile memory device including a memory cell array including a first memory cell having a first program status and connected to a first bit line during a plurality of program loops including different first and second program loops, and a second memory cell having a second program status that is a higher level status than the first program status and connected to a second bit line different from the first bit line during the plurality of program loops, and a page buffer configured to apply a pre-charge voltage to the first and second bit lines in a first verify operation for the second program status during the first program loop and apply the pre-charge voltage to the second bit line in a second verify operation for the second program status during the second program loop is provided.

According to the disclosed embodiment, an operation method of an non-volatile memory device including applying a first program voltage during a first program loop, providing, during the first program loop, a pre-charge voltage to a first bit line connected to a first memory cell having a first program status, and a second bit line connected to a second memory cell with a second program status that is a higher level status than the first program status and different from the first bit line, checking whether the first program status passes verification, comparing the first program status with a predetermined program status, applying a second program voltage different from the first program voltage during a second program loop after the comparison, and providing the pre-charge voltage to a third bit line connected to a third memory cell having a third program status that is a level higher than the second program status during the second program loop is provided.

### BRIEF DESCRIPTION OF THE DRAWINGS

FIG. 1 is a block diagram showing a non-volatile memory device according to an embodiment.

FIG. 2 is a view to explain a 3-dimensional structure of a memory cell array according to an embodiment.

FIG. 3 and FIG. 4 are views to explain a page buffer according to an embodiment.

FIG. 5 is a status table showing a status of a memory cell storing 3-bit data and bit data corresponding to a status according to an embodiment.

FIG. 6 is a flowchart to explain a program operation method of a non-volatile memory device according to an embodiment.

FIG. 7 and FIG. 8 are views to explain a program loop in a program operation method of a non-volatile memory device according to an embodiment.

FIG. 9 to FIG. 12 are views to explain a first pre-charge operation according to an embodiment.

FIG. 13 to FIG. 14 are views to explain a second pre-charge operation according to an embodiment.

FIG. 15 is a flowchart to explain a program operation method of a non-volatile memory device according to an embodiment.

FIG. 16 is a time table for explaining a program operation method of a non-volatile memory device according to an embodiment.

FIG. 17 is a flowchart to explain a program operation method of a non-volatile memory device according to an embodiment.

FIG. 18 is a time table for explaining a program operation method of a non-volatile memory device according to an embodiment.

FIG. 19 is a block diagram showing a user device including a non-volatile memory device according to an embodiment.

FIG. 20 is a block diagram showing an application example of a memory system including a non-volatile memory device according to an embodiment.

FIG. 21 is a block diagram showing a data storage device including a non-volatile memory device according to an embodiment.

FIG. 22 is a block diagram showing a computing system including a non-volatile memory device according to an embodiment.

### DETAILED DESCRIPTION

The disclosure will be described more fully hereinafter with reference to the accompanying drawings, in which embodiments of the disclosure are shown. As those skilled in the art would realize, the described embodiments may be modified in various different ways, all without departing from the scope of the disclosure.

Parts unrelated to the description of the example embodiments are not shown to make the description clear, and like reference numerals designate like element throughout the specification.

In addition, unless explicitly described to the contrary, the word “comprise”, and variations such as “comprises” or “comprising”, will be understood to imply the inclusion of stated elements but not the exclusion of any other elements.

Additionally, a specific number stated in a claim, even if explicitly cited within the claim, should not be construed as limiting the specific number in a claim where such citation does not exist. For example, to aid understanding, subsequent dependent claims could include the phrases ‘at least one’ and ‘one or more’. However, the use of such a phrase should not be understood as a limitation described by the unclear article ‘one’ for the sake of one example.

Additionally, when conventions such as ‘at least one of A, B, or C’ are used, these phrases will be well understood by those skilled in the art. (i.e., ‘a system including at least one of A, B, or C’ includes the meaning of A alone, B alone, C alone, A and B, A and C, B and C, and/or A, B, and C together, but it is not limited to any one concept). Also, in detailed descriptions or claims or drawings, letters and/or phrases including two or more separated selectable terms should be considered as possible to include one, or either, or both terms. For example, the phrase ‘A or B’ should be understood as including the possibilities ‘A’, or ‘B’ or ‘A and B’.

Terms such as “module,” “unit,” and “part” used in this document refer to a component that performs at least one function or operation, and these components may be implemented as hardware or software, or as a combination of hardware and software.

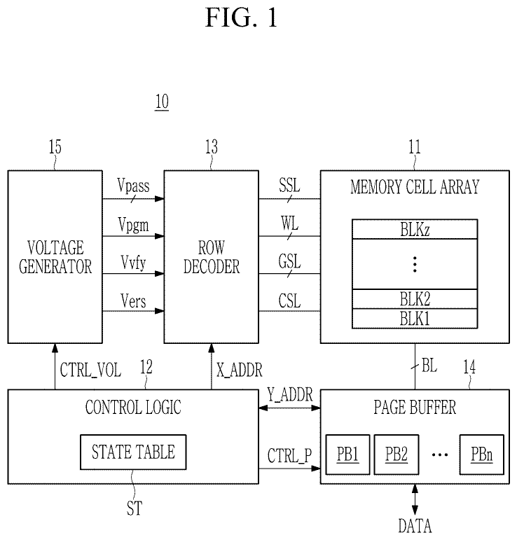

FIG. 1 is a block diagram showing a non-volatile memory device according to an embodiment.

Referring to FIG. 1, a non-volatile memory device 10 may include a memory cell array 11, a control logic 12, a row decoder 13, a page buffer circuit 14, and a voltage generator 15. Although not shown in FIG. 1, according to an embodiment, the non-volatile memory device 10 may further include a memory interface circuit, and may further include a column logic, a pre-decoder, a temperature sensor, a command decoder, an address decoder, etc.

The memory cell array 11 may be connected to a page buffer circuit 14 through a bit line BL, and may be connected to the row decoder 13 through a plurality of word lines WL, a plurality of string selection lines SSL, a plurality of ground selection lines GSL, and a common source line CSL.

The memory cell array 11 may include a plurality of memory blocks BLK1 to BLKz (hereinafter z is an integer of 2 or more) including a plurality of memory cells. For example, the memory cells may be flash memory cells. Hereinafter, embodiments of the disclosure will be described in detail, taking a case where the plurality of memory cells are NAND flash memory cells as an example. However, the disclosure is not limited thereto, and in some embodiments, the plurality of memory cells may be resistive memory cells, such as a resistive RAM (ReRAM), a phase change RAM (PRAM), a ferroelectric RAM (FRAM), or a magnetic RAM (MRAM).

Each memory cell included in the memory cell array 11 may store at least one bit or more. For example, the memory cell may be a single level cell (hereinafter, SLC) that stores 1-bit data. As another example, the memory cell may be a multi-level cell (hereinafter, MLC) that stores 2-bit data. As another example, the memory cell may be a triple level cell (hereinafter, TLC) that stores 3-bit data. For another example, the memory cell may be a quad level cell (or a quadruple level cell, hereinafter QLC) that stores 4-bit data. However, the disclosure is not limited thereto.

The plurality of memory blocks BLK1 to BLKz may include at least one of a single level cell block including the SLCs, a multi-level cell block including the MLCs, a triple level cell block including the TLCs, and a quad level cell block including the QLCs. Among the plurality of memory blocks included in the memory cell array 11, some memory blocks may be the single level cell blocks, and other blocks may be the multi level cell blocks or the triple level cell blocks.

When an erase voltage Vers is applied to the memory cell array 11, the plurality of memory cells may be in an erase status, and when the program voltage Vpgm is applied to the memory cell array 11, the plurality of memory cells may be in a program status. At this time, each memory cell may have an erase status and at least one program status classified according to the threshold voltage. For example, if the memory cell is a TLC that stores 3-bit data, the memory cell may have one of the erase status or the first to seventh status, but the types of the memory cells in the disclosure may be SLC, MLC, and QLC and is not limited to the examples.

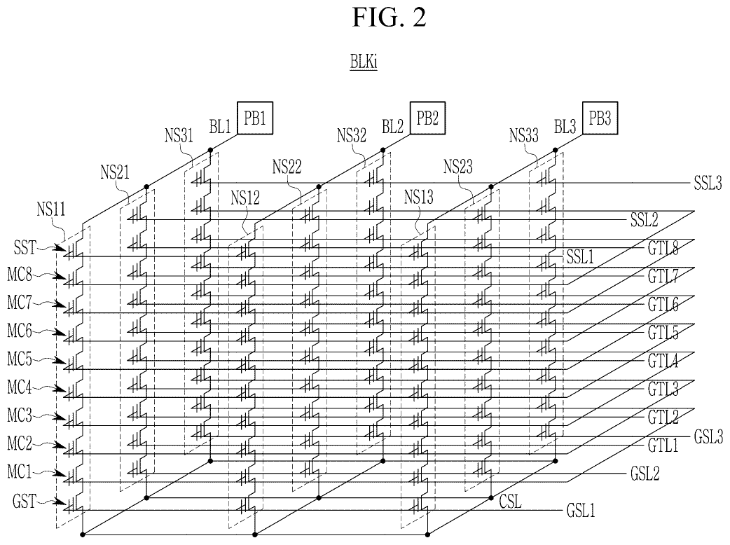

In an embodiment, the memory cell array 11 may include a 3-dimensional memory cell array, but the disclosure is not limited thereto and may be a 2-dimensional memory cell. The 3-dimensional memory cell array may include a plurality of cell strings, and each cell string may include memory cells each connected to the plurality of word lines stacked vertically on the substrate. For a detailed description of the structure of the 3-dimensional memory cell array, it is described in the explanation of FIG. 2.

The control logic 12 may generally control various operations within the non-volatile memory device 10. The control logic 12 may output various control signals in response to commands and/or addresses received from a controller (not shown). The control logic 12 may output the control signals to write or program the data DATA to the memory cell array 11, read the data DATA from the memory cell array 11, or erase the data stored in the memory cell array 11. For example, the control logic 12 may output voltage a control signal CTRL_vol, a row address X-ADDR, a column address Y-ADDR, and a page buffer control signal CTRL_P.

Various control signals output from the control logic 12 may be provided to the voltage generator 15, the row decoder 13, and the page buffer circuit 14. The control logic 12 may provide the voltage control signal CTRL_vol to the voltage generator 15. According to an embodiment, the control logic 12 may generate a voltage control signal CTRL_vol to control the generation of the program voltage Vpgm and the verify voltage Vvfy provided to the memory cell array 11 during the program operation.

According to an embodiment, when the plurality of memory cells are programmed, the control logic 12 can generally control various operations within the non-volatile memory 10 so that at least one program loop is performed sequentially. In the program loop, the control logic 12 may control the plurality of memory cells to receive at least one program voltage Vpgm and at least one verify voltage Vvfy or a pass voltage Vpass through the plurality of word lines WL.

The control logic 12 may control the voltage generator 15 to generate the program voltage Vpgm whose level changes as the number of the program loops increases. For example, as the number of the program loops increases in the program operation, the control logic 12 may control the voltage generator 15 to generate the program voltage Vpgm with the increased level. According to the embodiment, the control logic 12 may generate the program voltage Vpgm corresponding to the program status. As an example, when the control logic 12 performs a program operation on the triple level cell block, a first program voltage corresponding to the first status, which is one of the program statuses, may be generated during the preceding program loop. When performing the program operation on the triple level cell block, the control logic 12 may control the voltage generator 15 to generate a seventh program voltage corresponding to the seventh status of one of the program statuses during the subsequent program loop and having a level higher than the first program voltage.

The control logic 12 may control the voltage generator 15 to apply at least one program voltage Vpgm within one program loop. After applying at least one program voltage Vpgm, within one program loop, the control logic 12 may control the voltage generator 15 to apply at least one verify voltage Vvfy. The control logic 12 may control the page buffer circuit 14 to sense whether a memory cell is an off cell based on the applied verify voltage Vvfy. Here, the off cell may be a memory cell with a threshold voltage higher than the applied verify voltage. Conversely, an on cell may be a memory cell with a threshold voltage lower than the applied verify voltage.

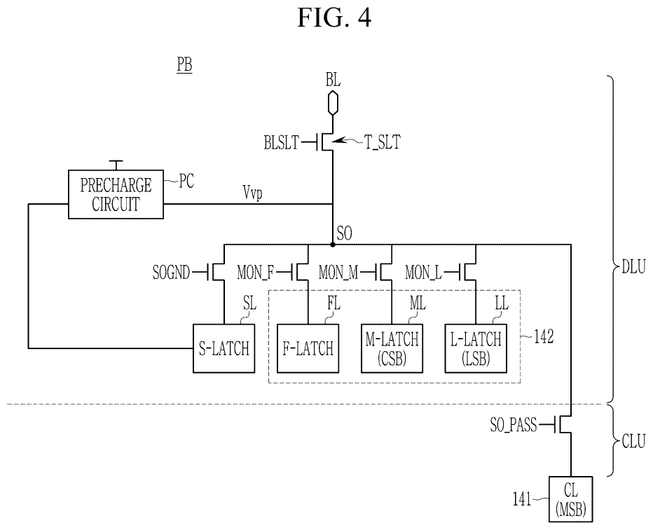

In the sensing operation, the control logic 12 may control the page buffer circuit 14, for the plurality of memory cells that are a target of the verify operation, to provide the pre-charge voltage (Vvp in FIG. 4) through the bit line BL in addition to providing the verify voltage Vvfy,

Hereinafter, the process where the non-volatile memory device 10 provides the pre-charge voltage (Vvp in FIG. 4) to the memory cell through the bit line BL and provides the verify voltage Vvfy to the memory cell to sense whether the memory cell to be targeted is the off-cell may be called ‘a verify operation’ or ‘a verification operation’.

As an example, the control logic 12 may perform the first program loop for the plurality of memory cells. The control logic 12 may control the voltage generator 15 to apply the first program voltage in the first program loop. Also, the control logic 12 may control the voltage generator 15 to apply the first verify voltage in the first program loop. The control logic 12 may control the page buffer circuit 14 to sense whether the memory cell is the off-cell based on the first verify voltage. Here, the off-cell may be a memory cell with a threshold voltage lower than the first verify voltage.

The control logic 12 may count the number of the off-cells based on the sensing operation regarding the presence or absence of the off-cell. The control logic 12 may compare the count value for the off cell with a previously stored reference value, and according to the comparison result, check whether the first status, which is one of the program statuses, passes (e.g., passes verification), and determine a second program voltage in the second program loop after the first program loop. According to the embodiment, depending on whether the first status passes, the control logic 12 may stop applying the verify voltage for the first status during one subsequent program operation.

The control logic 12 may control the page buffer circuit 14 to apply the pre-charge voltage in different ways based on the status table ST. According to an embodiment, the status table ST may include corresponding information between at least one program status for the memory cell and bit data stored in a latch circuit within the page buffer circuit 14. Hereinafter, the process where the page buffer circuit 14 applies the pre-charge voltage to the memory cell that is the target of the verify operation through the bit line BL is referred to as ‘a pre-charge operation’.

The control logic 12 may control the page buffer circuit 14, when performing the pre-charge operation on some memory cells, so as to perform a first pre-charge operation that applies the pre-charge voltage to the memory cell that is the verification target and the memory cell that has a lower level status than the verify target. Additionally, control logic 12 may control the page buffer circuit 14 to perform a second pre-charge operation that selectively applies the pre-charge voltage to the memory cells to be verified when performing the pre-charge operation on some memory cells. In other words, the pre-charge voltage may be not applied for the memory cell that is not subject to the verification in the second pre-charge operation.

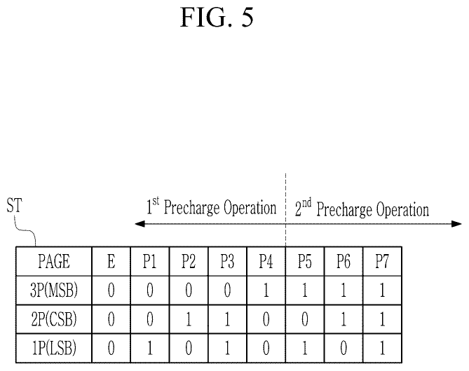

According to an embodiment, the control logic 12 may perform the first pre-charge operation on the memory cell with a relatively lower level status and the second pre-charge operation on the memory cell with a relatively higher level status, based on the status table ST. The specific descriptions related to the first and second pre-charge operations are described in FIG. 5 to FIG. 14 later.

The voltage generator 15 may be connected to the memory cell array 11 through the plurality of word lines WL. The voltage generator 15 may generate various types of voltages to perform the program, read, and erase operations on the memory cell array 11 based on the voltage control signal CTRL_vol. The voltage generator 15 may generate, for example, the program voltage Vpgm, the verify voltage Vvfy, the pass voltage Vpass, and the erase voltage Vers. According to an embodiment, the pass voltage Vpass may be a voltage applied to an unselected word line during the read or verify operation.

The program voltage Vpgm, the verify voltage Vvfy, etc. generated by the voltage generator 15 may be provided to the word line selected from the plurality of word lines WL. The selected word line may be at least one word line selected by the row address X-ADDR.

According to an embodiment, the voltage generator 15 may generate the program voltage Vpgm and at least one verify voltage Vvfy, whose level changes as the number of the program loops increases, based on the voltage control signal CTRL_vol.

When the program loop is performed, the program operation according to an embodiment may be performed in an ISPP (Incremental Step Pulse

Programming) method, and the voltage generator 15 may generate the program voltage whose voltage level is higher than the previous program voltage every time the program loop is performed.

The row decoder 13 may select the specific word line among the word lines WL in response to the row address X-ADDR received from the control logic 12. Specifically, during the program operation, the row decoder 13 may provide the program voltage Vpgm to the selected word line. Additionally, the row decoder 13 may select some string selection line among the string selection line SSL or some ground selection line among the ground selection line GSL in response to the row address X-ADDR received from the control logic 12.

During one program loop during the program operation, the row decoder 13 may apply the program voltage Vpgm to the selected word line and the verify voltage Vvfy to the selected word line. According to an embodiment, the row decoder 13 may apply the pass voltage Vpass to the remaining unselected word lines while the verify voltage Vvfy is applied.

The page buffer circuit 14 may be connected to the memory cell array 11 through the plurality of bit lines BL. The page buffer circuit 14 may select some bit lines from the plurality of bit lines BL in response to the column address Y-ADDR received from the control logic 12. During the program operation or the read operation, the page buffer circuit 14 operates as a sense amplifier and may sense the data DATA stored in the memory cell array 11. Meanwhile, during the program operation, the page buffer circuit 14 operates as a write driver and may input the data DATA to be stored in the memory cell array 11.

The page buffer circuit 14 may store the data DATA read from the memory cell array 11, or store the data DATA to be written into the memory cell array 11. The page buffer circuit 14, by the control of the control logic 12, may provide the pre-charge voltage Vvp of FIG. 4, to sense whether the memory cell is the off-cell based on the verify voltage Vvfy. The page buffer circuit 14 may temporarily store whether there is the sensed off-cell. The control logic 12 may check whether the program status passes (e.g., passes verification) by counting and comparing the memory cells that are the off cells.

The page buffer circuit 14 may include a plurality of page buffers (PB1-PBn, hereinafter n is an integer of 2 or more) respectively connected to the plurality of bit lines BL. The plurality of page buffers PB1 to PBn may be arranged to correspond to each bit line, and each page buffer may include a plurality of latch circuits. Hereinafter, the page buffer circuit will be defined as including the page buffer connected to each bit line. However, the embodiments of the disclosure may define the terms differently, as an example, one page buffer may be provided corresponding to the plurality of bit lines, and a unit of the configurations arranged corresponding to each bit line may be defined as a page buffer unit.

FIG. 2 is a view to explain a 3-dimensional structure of a memory cell array according to an embodiment.

Referring to FIG. 1 and FIG. 2, a plurality of memory blocks BLK1 to BLKz, respectively, as shown in FIG. 2, the memory block BLKi may be expressed as an equivalent circuit. The memory block BLKi of FIG. 2 may be any one of the plurality of memory blocks BLK1 to BLKz, and represents a 3-dimensional memory block formed as a three-dimensional structure on a substrate. For example, the plurality of memory NAND strings included in the memory block BLKi may be formed in a vertical direction to the substrate.

The memory block BLKi may include a plurality of memory NAND strings NS11 to NS33 connected between the plurality of bit lines BL1, BL2, and BL3 and the common source line CSL. Each of the plurality of memory NAND strings NS11 to NS33 may include a string selection transistor SST, a plurality of memory cells MC1, MC2, . . . , MC8, and a ground selection transistor GST. In FIG. 2, each of the plurality of memory NAND strings NS11 to NS33 is shown as containing eight memory cells MC1, MC2, . . . , MC8, but is not necessarily limited thereto.

The string selection transistor SST may be connected to the corresponding string selection lines SSL1, SSL2, and SSL3. The plurality of memory cells MC1, MC2, . . . , MC8 may each be connected to the corresponding gate lines GTL1, GTL2, . . . , GTL8. The gate lines GTL1, GTL2, . . . , GTL8 may correspond to the word lines, and a part of the gate lines GTL1, GTL2, . . . , GTL8 may correspond to dummy word lines. The ground selection transistor GST may be connected to the corresponding ground selection lines GSL1, GSL2, and GSL3. The string selection transistor SST may be connected to the corresponding bit lines BL1, BL2, and BL3, and the ground selection transistor GST may be connected to the common source line CSL. Each bit line BL1, BL2, and BL3 may be connected to the corresponding page buffers PB1, PB2, and PB3. Each page buffer PB1, PB2, and PB3 may be the page buffer PB1 to PBn.

The word lines (e.g., WL1) of the same height are commonly connected, and the ground selection lines GSL1, GSL2, and GSL3 and the string selection lines SSL1, SSL2, and SSL3 may be separated, respectively. In FIG. 2, the memory block BLK is shown as being connected to eight gate lines GTL1, GTL2, . . . , GTL8 and three bit lines BL1, BL2, and BL3, but is not necessarily limited thereto. For example, a fourth bit line, which may be configured to receive a pre-charge voltage Vvp in a first verify operation (in which two other bit lines may also receive the pre-charge voltage Vvp), may be included and may be connected to a memory cell.

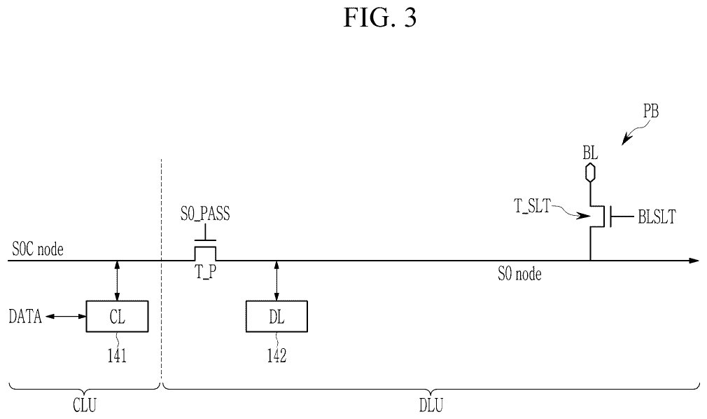

FIG. 3 and FIG. 4 are views to explain a page buffer according to an embodiment. FIG. 4 is a view specifically showing a data latch unit DLU in FIG. 3.

Referring to FIG. 1, FIG. 3, and FIG. 4, the page buffer PB may include a cache latch unit CLU and a data latch unit DLU. The page buffer PB may correspond to one of the plurality of page buffers PB1 to PBn of FIG. 2.

The cache latch unit CLU may include the cache latch 141. For example, the cache latch 141 may receive and store the data DATA to be written to the memory cell from the outside (e.g., from outside of the non-volatile memory device 10). Additionally, the cache latch 141 may store the data DATA transmitted from the data latch 142 and provide it to the outside.

The cache latch 141 may be placed relatively further apart than the distance between other latch circuits in order to exchange the data DATA with the outside of the page buffer PB. For example, since the data movement time between the cache latch 141 and an external data input/output circuit (not shown) is relatively longer than the data movement time between the cache latch 141 and the latches included in the data latch unit DLU, to compensate this, the cache latches 141 may be placed relatively further apart than the distance between the latches included in the data latch unit DLU. However, a dumping time between cache latch 141 and the latch included in the data latch unit DLU may become long. The dumping time may refer to a time it takes for data to be copied and moved between the latches.

The cache latch 141 may be connected to a coupling sensing node SOC. The cache latch 141 and the data latch 142 are capable of transmitting/receiving the data DATA through the coupling sensing node SOC. In the drawing, one cache latch 141 is shown as being placed in the cache latch unit CLU, but according to an embodiment, two cache latches 141 or more may be included. The coupling sensing node SOC may be connected to a sensing node SO through a pass transistor T_P.

According to an embodiment, the cache latch 141 may store an most significant bit data MSB for the program status of the memory cell connected (e.g., electrically connected) to the bit line BL during the program operation, and may be dumped to a sensing latch SL through the sensing node SO by a pass signal SO_PASS. According to an embodiment, the most significant bit data MSB, during the pre-charge operation, is one of the bit data used to check the status of the target program to be programmed in the memory cell connected (e.g., electrically connected) to the bit line BL. According to an embodiment, the most significant bit data MSB may be copied to the sensing latch SL in the pre-charge operation and dumped.

The data latch unit DLU may include a pass transistor T_P, a data latch 142, a sensing latch SL, a pre-charge circuit PC, and a bit line selection transistor T_SLT.

The pass transistor T_P may be turned on or turned off depending on the pass signal SO_PASS. When the pass transistor T_P is turned on, the data DATA may be copied and dumped between the cache latch 141 and the data latch 142. According to an embodiment, the pass transistor T_P may provide the most significant bit data MSB to the data latch unit DLU according to the pass signal SO_PASS during the pre-charge operation. According to an embodiment, the pass signal SO_PASS may be any one of the page buffer control signals CTRL_P provided from the control logic 12.

The data latch 142 may include a force latch FL, a high-order bit latch ML, and a low-order bit latch LL. According to an embodiment, the force latch FL, the high-order bit latch ML, and the low-order bit latch LL may be electrically connected to the sensing node SO by the transistor that operates in response to various control signals MON_F, MON_M, and MON_L. According to an embodiment, the various control signals MON_F, MON_M, and MON_L may be the page buffer control signal CTRL_P provided from the control logic 12.

The data latch 142 may store the data (hereinafter, write bits) written to the memory cell connected (e.g., electrically connected) to the bit line BL. The high-order bit latch ML, the low-order bit latch LL, and the cache latch 141 may be used to store the data DATA input externally during program operation. The bit data stored in the high-order bit latch ML, the low-order bit latch LL, and the cache latch 141 may correspond to the target program status to be programmed in the memory cell.

According to an embodiment, the force latch FL may be used to improve a threshold voltage distribution during the program operation. According to an embodiment, the high-order bit latch ML may store central significant bit data CSB about the program status of the memory cell connected (e.g., electrically connected) to the bit line BL during the program operation. The central significant bit data CSB may be dumped to the sensing latch SL through the sensing node SO by the high-order bit latch control signal MON_M. The low-order bit latch LL may store least significant bit data LSB for the program status of the memory cell connected (e.g., electrically connected) to the bit line BL during the program operation. The least significant bit data LSB may be dumped into the sensing latch SL through the sensing node SO by the low-order bit latch control signal MON_L.

The sensing latch SL may be controlled by a ground control signal SOGND in the verify operation, the read operation, the pre-charge operation, the program operation, etc. of the page buffer PB. According to an embodiment, the ground control signal SOGND may be the page buffer control signal CTRL_P provided from control logic 12.

According to an embodiment, the sensing latch SL may detect the voltage of the bit line BL in the verify operation or the read operation to be stored as a sensing bit. According to an embodiment, the sensing latch SL, in the pre-charge operation, may receive part of the most significant bit data MSB, the central significant bit data CSB, and the least significant bit data LSB from the cache latch 141, the high-order bit latch ML, and the low-order bit latch LL. According to an embodiment, the sensing latch SL may sense whether the memory cell is the off-cell by sensing and storing the voltage change of the bit line BL in the verify operation of the program operation.

According to an embodiment, in the first pre-charge operation, the part of the most significant bit data MSB, the central significant bit data CSB, and the least significant bit data LSB may be dumped into the sensing latch SL. According to an embodiment, in the second pre-charge operation, the central significant bit data CSB and the least significant bit data LSB may be dumped into the sensing latch SL. According to an embodiment, in the second pre-charge operation, the dumping operation for the most significant bit data MSB may not be performed.

Assuming that the memory cell connected (e.g., electrically connected) to the bit line BL is a TLC, it is explained above that the latch circuit in the page buffer PB stores the 3-bit data, but the number of the bit data stored is only an example and is not limited thereto. Similarly, according to an embodiment, the number of latch circuits included in the data latch 142 may also be changed in various ways.

According to an embodiment, the pre-charge circuit PC, in response to the page buffer control signal CTRL_P, based on some (e.g., based on at least part of) bit data of the most significant bit data MSB, the central significant bit data CSB, and the least significant bit data LSB, may provide the pre-charge voltage Vvp of a specific level to the bit line BL.

According to an embodiment, in the first pre-charge operation, the pre-charge circuit PC, based on whether some of the dumped bit data among the most significant bit data MSB, the central significant bit data CSB, and the least significant bit data LSB is logic low, may apply the pre-charge voltage of a specific level to the memory cell that is the verification target and the memory cell that has a lower level status than the verify target.

According to an embodiment, in the second pre-charge operation, the pre-charge circuit PC, based on the central significant bit data CSB and the least significant bit data LSB, may selectively apply the pre-charge voltage of a specific level to the memory cell of the verification target. According to an embodiment, in the second pre-charge operation, the pre-charge voltage may not be applied to the memory cells that are not subject to the verification.

The sensing node SO may be pre-charged during the read, program or erase operations of the non-volatile memory device 10. For example, the sensing node SO may be connected (e.g., electrically connected) to the bit line BL through the bit line selection transistor T_SLT. The bit line selection transistor T_SLT may be turned on or turned off depending on the bit line selection signal BLSLT. According to an embodiment, the bit line selection transistor T_SLT may be an NMOS transistor and may be implemented as a high voltage transistor, but is not limited thereto.

FIG. 5 is a status table showing a status of a memory cell storing 3-bit data according to an embodiment and bit data corresponding to a status.

Referring to FIG. 1, FIG. 4, and FIG. 5, the status table ST may include an information corresponding to an erase status E and first to seventh status P1 to P7 of a program status. According to an embodiment, the erase status E, and the first to seventh status P1 to P7 may be higher level status in the order thereof. That is, the seventh status P7 may be the highest level status, and the erase status E may be the lowest level status. The corresponding information may include bit data stored in the latch circuit in the page buffer PB corresponding to the program status.

The corresponding information for the erase status E may include the most significant bit data MSB with logic low, the central significant bit data CSB with logic low, and the least significant bit data LSB with logic low.

The corresponding information for the first status P1 may include the most significant bit data MSB with logic low, the central significant bit data CSB with logic low, and the least significant bit data LSB with logic high. The corresponding information for the second status P2 may include the most significant bit data MSB with logic low, the central significant bit data CSB with logic high, and the least significant bit data LSB with logic low. The corresponding information for the third status P3 may include the most significant bit data MSB with logic low, the central significant bit data CSB with logic high, and the least significant bit data LSB with logic high. The corresponding information for the fourth status P4 may include the most significant bit data MSB with logic high, the central significant bit data CSB with logic low, and the least significant bit data LSB with logic low.

According to an embodiment, the control logic 12 may control the page buffer circuit 14 to perform the first pre-charge operation for the memory cells to be programmed with the first to fourth status P1 to P4. According to an embodiment, in the first pre-charge operation, the page buffer circuit 14 may perform the dumping operation on a portion of the most significant bit data MSB, the central significant bit data CSB, and the least significant bit data LSB. The page buffer circuit 14 may apply the pre-charge voltage Vvp of a specific level to the memory cell that is the verification target and the memory cell that has a lower level status than the verify target based on whether some of the dumped bit data is logic low.

The corresponding information for fifth status P5 may include the most significant bit data MSB with logic high, the central significant bit data CSB with logic low, and the least significant bit data LSB with logic high. The corresponding information for the sixth status P6 may include the most significant bit data MSB with logic high, the central significant bit data CSB with logic high, and the least significant bit data LSB with logic low. The corresponding information for the seventh status P7 may include the most significant bit data MSB with logic high, the central significant bit data CSB with logic high, and the least significant bit data LSB with logic high.

According to an embodiment, the control logic 12 may control the page buffer circuit 14 to perform the second pre-charge operation for the memory cell to be programmed with fifth to seventh status P5 to P7. According to an embodiment, in the second pre-charge operation, the page buffer circuit 14 may perform the dumping operation for the central significant bit data CSB and the least significant bit data LSB. The page buffer circuit 14 may selectively apply a specific level of the pre-charge voltage Vvp to the memory cell subject to the verification based on the dumped central significant bit data CSB and least significant bit data LSB.

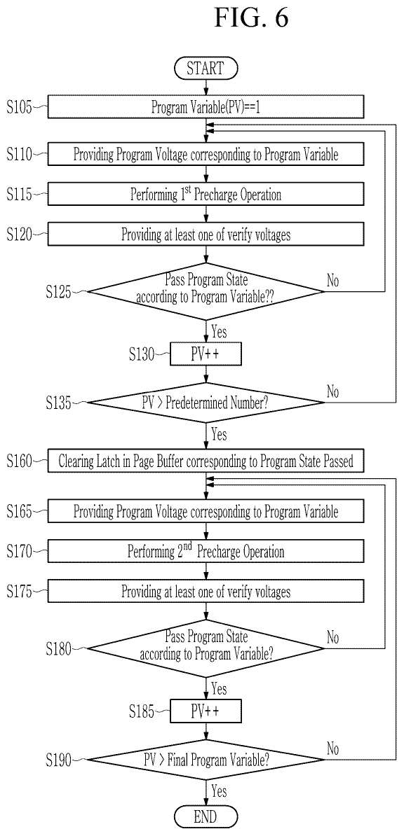

FIG. 6 is a flowchart to explain a program operation method of a non-volatile memory device according to an embodiment.

Referring to FIG. 1, FIG. 5, and FIG. 6, the control logic 12 sets a program variable PV as ‘1’ (S105).

The program variable PV is a variable defined in the disclosure to facilitate the description of a program loop operation described later of the non-volatile memory device 10. In the technical field of the disclosure, the program variable PV may be referred to and defined differently.

According to an embodiment, when programming the memory cell from the erase status E to the target program status, the non-volatile memory device 10 may perform program operations with sequential shift programming.

For example, the memory cell that is the TLC with the seventh status P7 as a target program status is transitioned from the erase status E to the first to seventh status P1 to P7 according to the sequential shift programming, thereby having the seventh status P7, which is the target program status. The following program operation of the non-volatile memory device 10 is explained assuming that the memory cell is the TLC, but the disclosure is not limited thereto.

According to an embodiment, the control logic 12 may initially set the program variable PV to ‘1’ in the transition order of the program status of the memory cell.

The row decoder 13 provides the program voltage Vpgm corresponding to the predetermined program variable PV to the selected word line (S110).

According to an embodiment, the control logic 12 may control the voltage generator 15 so that as the program variable PV increases, the level of the corresponding program voltage Vpgm increases. As an example, the voltage level of the program voltage Vpgm corresponding to the program variable PV of ‘2’ may be higher than the voltage level of the program voltage Vpgm corresponding to the program variable PV of ‘1’.

According to an embodiment, the non-volatile memory device 10 may perform the program operation on the memory cell using ISPP (Incremental step pulse programming). When the same program variable PV is set, the voltage generator 15 may generate the program voltage whose voltage level is higher than the previous program voltage as the program loop is performed.

While performing the step (S110), the row decoder 13 may provide a specific level of the pass voltage to the unselected word line. According to an embodiment, while the row decoder 13 applies the program voltage Vpgm, the page buffer circuit 14 may apply the program voltage of a low voltage (e.g., a ground voltage) or a program inhibit voltage to the plurality of bit lines BL depending on the speed at which the memory cell is programmed. According to an embodiment, the program prohibition voltage may be equal to the program voltage Vpgm applied to the selected word line.

The page buffer circuit 14 performs the first pre-charge operation (S115).

According to an embodiment, the page buffer circuit 14 may perform the first pre-charge operation based on a part of the most significant bit data MSB, the central significant bit data CSB, and the least significant bit data LSB.

According to an embodiment, in the first pre-charge operation, the page buffer circuit 14, based on whether some of the dumped bit data among the most significant bit data MSB, the central significant bit data CSB, and the least significant bit data LSB is logic low, may apply together the pre-charge voltage of a specific level to the memory cell that is the target of the verify operation and to the memory cell that has a lower level status than the target of the verify operation.

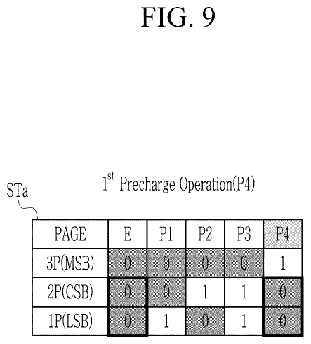

A detailed description of the first pre-charge operation is described later in FIG. 9 to FIG. 12.

The row decoder 13 provides at least one verify voltage Vvfy to the selected word line (S120).

The control logic 12 may control the row decoder 13 so that at least one verify voltage Vvfy is applied to the selected word line after applying the program voltage Vpgm. According to an embodiment, after the program voltage Vpgm is applied, within one program loop, the row decoder 13 may provide a plurality of verify voltages to the selected word line to verify the different program statuses.

According to an embodiment, the page buffer circuit 14, based on the applied verify voltage(s), may sense whether the memory cell on which the first pre-charge operation was performed is the off-cell. According to an embodiment, the page buffer circuit 14 may sense whether the memory cell on which the first pre-charge operation was performed is the off-cell based on the verify voltage Vvfy corresponding to the program variable PV and temporarily store the off-cell information. Afterwards, the control logic 12 may check whether the program status corresponding to the program variable PV passes (e.g., passes verification) based on the off-cell information.

In the same program loop, the control logic 12 may control the row decoder 13 and the voltage generator 15 so as to provide the verify voltage Vvfy corresponding to the predetermined program variable PV to the selected word line, and not to provide the verify voltage Vvfy for verifying the lower level status than the predetermined program variable PV to the selected word line.

According to an embodiment, in the same program loop, the control logic 12 may control the row decoder 13 and the voltage generator 15 so that the verify voltage Vvfy corresponding to the predetermined program variable PV and the verify voltage for verifying the higher level status than the predetermined program variable PV are provided to the selected word line. According to an embodiment, the plurality of verify voltages may be provided to the selected word line in the reverse order of the voltage level.

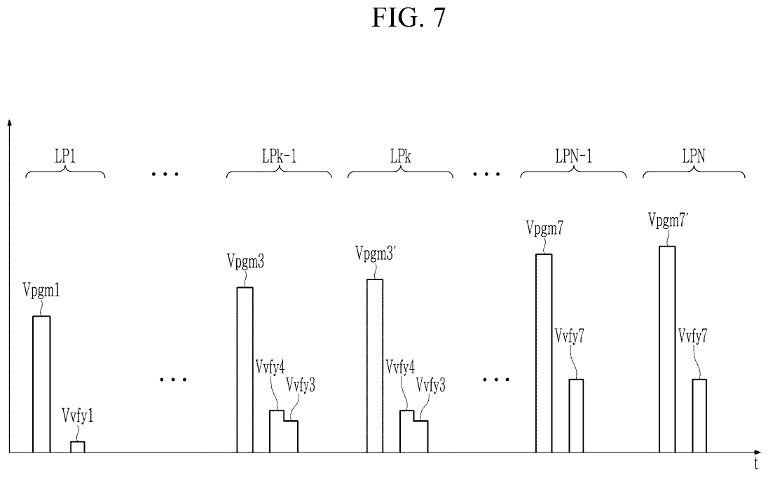

Explaining the (k−1)-th program loop LP(k−1) in FIG. 7 as an example, the row decoder 13 may provide the third program voltage Vpgm3 corresponding to the program variable PV of ‘3’ to the selected word line. During the (k−1)-th program loop LP(k−1), the control logic 12 may control the row decoder 13 and the voltage generator 15 so that the third verify voltage Vvfy3 for verifying the third status P3 corresponding to the program variable PV of ‘3’ and the fourth verify voltage Vvfy4 for verifying the fourth status P4, which is a higher level status than the third status P3, are provided to the selected word line. During the (k−1)-th program loop LP(k−1), the control logic 12 may control the row decoder 13 and the voltage generator 15 not to provide the verify voltage for verifying the first status P1 and the second status P2 having the lower level statuses than the third status P3 corresponding to the program variable PV of ‘3’ to the selected word line. To further explain the example, the row decoder 13 may provide the verify voltage Vvfy to the selected word line in the order of the fourth verify voltage Vvfy4 and the third verify voltage Vvfy3.

In FIG. 6, the step (S115) and the step (S120) are shown as being performed separately, but according to an embodiment, one first pre-charge operation and one verify voltage application operation may be performed together as one verify operation.

Describing the (k−1)-th program loop LP(k−1) in FIG. 7 as an example, the control logic 12 may control the configurations of the non-volatile memory device 10 to be performed in the order of the first pre-charge operation in the step (S115) during the (k−1)-th program loop LP(k−1), the application operation of the fourth verify voltage Vvfy4 in the step (S120), the first pre-charge operation in the step (S115), and the application operation of the third verify voltage Vvfy3 in the step (S120). The first pre-charge operation in the step (S115) and the application operation of the fourth verify voltage Vvfy4 in the step (S120) may be operated together as one verify operation. The first pre-charge operation in the step (S115) and the application operation of the third verify voltage Vvfy3 in the step (S120) may be operated together as one verify operation.

The control logic 12 checks whether the program status corresponding to the program variable PV passes (e.g., passes verification) based on the verify operation (S125).

According to an embodiment, the control logic 12 may count the off-cell information temporarily stored in the page buffer circuit 14. According to an embodiment, the control logic 12 may compare the count value for off-cell with a predetermined reference value. According to an embodiment, control logic 12 may determine the pass of the program status P if the count value for the off cell is greater than the predetermined reference value.

If the program status corresponding to the program variable PV is not the pass, the steps S110 to S125 may be performed repeatedly. According to an embodiment, the steps S110 to S125 may be operated as one program loop (e.g., a first verify operation).

If the program status corresponding to the program variable PV is the pass, the predetermined program variable PV is increased (S130).

For example, if the memory cell is the TLC and the program variable PV is ‘a’ that is a positive integer less than or equal to ‘7’, the program variable PV may be increased to “a+1” through the increase operation. According to an embodiment, the type of the memory cell may change, and as the type of the memory cell changes, the upper limit of the program variable PV may also change.

According to an embodiment, for the memory cell having the past program status as the target program status, the page buffer circuit 14 may provide a program inhibition voltage through the bit line BL during the application operation of the program voltage Vpgm. According to an embodiment, through the operation of the page buffer circuit 14, a program may not be performed on the memory cell having the already passed program status as the target program status. According to an embodiment, for the memory cell with the erase status E as the target program status, the program inhibition voltage may be provided through the bit line BL, so the program may not be performed.

The increased program variable PV is compared with a predetermined number (S135).

According to an embodiment, if the memory cell is the TLC, the predetermined number may be ‘4’. According to an embodiment, if the increased program variable PV is less than or equal to the predetermined number ‘4’, the steps (S110) to (S135) may be repeatedly performed.

According to an embodiment, the comparison operation of the step (S135) may be a step of checking and comparing whether the program status that is passed (e.g., that passes verification) directly before is a predetermined program status. According to an embodiment, the comparison operation of the step (S135) may be an operation that checks and compares whether the previously passed program status is the fourth status P4 when the memory cell is the TLC.

If the increased program variable PV is greater than the predetermined number, the control logic 12 clears the latch circuit in the page buffer PB corresponding to the passed program status (S160).

According to an embodiment, the control logic 12 may clear the data latch 142 and the cache latch 141 in the page buffer PB, which stores the bit data MSB, CSB, and LSB corresponding to the passed program status. According to an embodiment, the control logic 12 may clear the data latch 142 and the cache latch 141 in the page buffer PB, which stores the bit data MSB, CSB, and LSB corresponding to the first to fourth status P1 to P4.

The page buffer PB that is the target of the clear operation may store the most significant bit data MSB of logic low, the central significant bit data CSB of logic low, and the least significant bit data LSB of logic low, corresponding to the erase status E.

Through the clear operation of the step (S160), the page buffer circuit 14 in the next program loop may operate the memory cell connected to the page buffer PB that is the target of the clear operation like the memory cell whose target program status is the erase status E.

The row decoder 13 provides the program voltage Vpgm corresponding to the predetermined program variable PV to the selected word line (S165).

The step S165 may correspond to the step S110 described above. For ease of the explanation, the description of the step (S165) may be replaced with the description of the step (S110).

The page buffer circuit 14 performs the second pre-charge operation (S170).

According to an embodiment, the page buffer circuit 14 may perform the second pre-charge operation based on the central significant bit data CSB and the least significant bit data LSB.

According to an embodiment, in the second pre-charge operation, the page buffer circuit 14 may perform the dumping operation on the central significant bit data CSB and the least significant bit data LSB. The page buffer circuit 14 may not perform the dumping operation on the most significant bit data MSB during the dumping operation on the central significant bit data CSB and the least significant bit data LSB. The page buffer circuit 14 may selectively apply the pre-charge voltage of a specific level to the memory cell subject to the verification based on the dumped central significant bit data CSB and least significant bit data LSB. Additionally, in the second pre-charge operation, the pre-charge voltage may be not applied to the memory cells that are not subject to the verification.

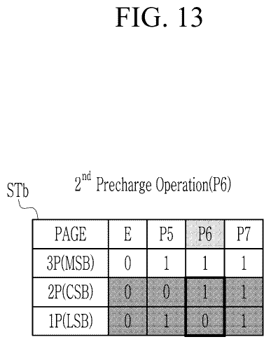

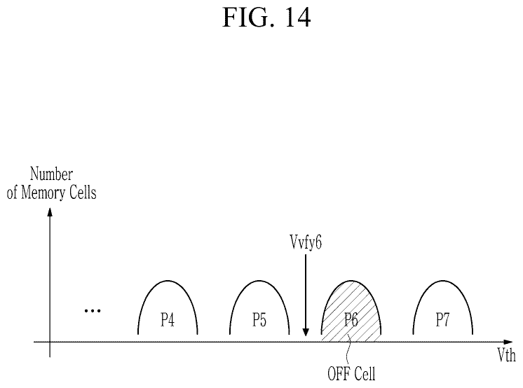

The detailed description of the second pre-charge operation is described later in FIG. 13 and FIG. 14.

The row decoder 13 provides at least one verify voltage Vvfy to the selected word line (S175).

The step (S175) may correspond to the step (S120) described above. For ease of the explanation, the description of the step (S175) is focused on differences from the description of the step (S120).

According to an embodiment, the page buffer circuit 14 may sense whether the memory cell on which the second pre-charge operation was performed is the off-cell based on the applied verify voltage. According to an embodiment, the page buffer circuit 14, based on the verify voltage Vvfy corresponding to the program variable PV, may sense whether the memory cell on which the second pre-charge operation was performed is the off-cell and store the off-cell information temporarily.

In FIG. 6, the steps (S170 and S175) are shown as being performed separately, but according to an embodiment, one second pre-charge operation and one verify voltage application operation may be performed together as one verify operation.

The control logic 12 checks whether the program status corresponding to the program variable PV passes (e.g., passes verification) based on the verify operation (S180).

The step (S180) may correspond to the step (S125) described above. For ease of the explanation, the description of the step (S180) is focused on differences from the description of the step (S125).

If the program status corresponding to the program variable PV is not passed, the steps (S165 to S180) may be performed repeatedly. According to an embodiment, the steps (S165 to S180) may be operated as one program loop (e.g., a second program loop and/or a second verify operation).

If the program status corresponding to the program variable PV is passed (e.g., passes verification), the predetermined program variable PV is increased (S185).

The step S185 may correspond to the step S130 described above. For ease of explanation, the description of the step (S185) may be replaced with the description of the step (S130).

The increased program variable PV is compared with the final program variable (S190).

According to an embodiment, if the memory cell is the TLC, the final program variable may be ‘7’. According to an embodiment, if the increased program variable PV is less than or equal to ‘7’, which is the predetermined final program variable, the steps (S165 to S190) may be repeatedly performed. According to an embodiment, the memory cell is not limited to the example and may be an MLC or a QLC, and depending on the type of the memory cell, the final program variable may change.

According to an embodiment, the comparison operation of the step (S190) may be an operation to confirm the end of the program operation. According to an embodiment, the comparison operation of the step (S190) may be, for example, an operation that checks and compares whether the previously passed program status is the seventh status P7, which is the final program status, when the memory cell is the TLC.

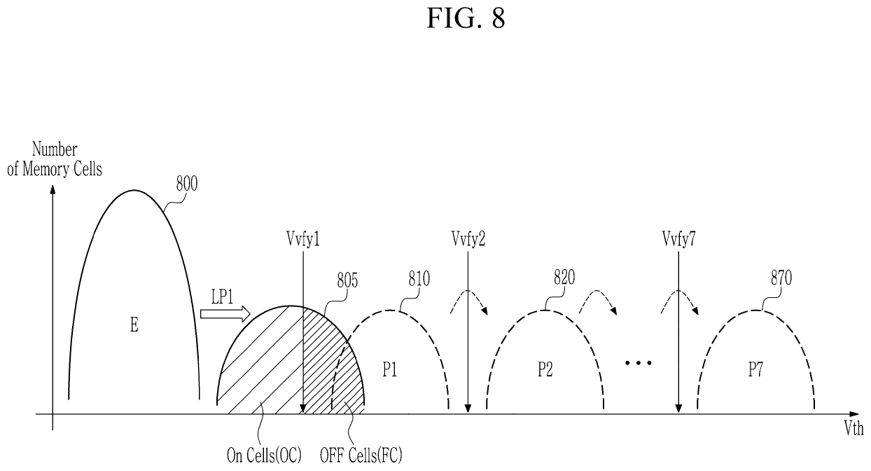

FIG. 7 and FIG. 8 are views to explain a program loop in a program operation method of a non-volatile memory device according to an embodiment. FIG. 7 specifically represents pulses applied to a selected word line while performing a program operation of a memory cell of a TLC. FIG. 8 specifically shows a change in a threshold voltage distribution during a program operation for a memory cell of a TLC.

Referring to FIG. 1, FIG. 6, FIG. 7, and FIG. 8, the non-volatile memory device 10 may perform first to N-th program loops LP1 to LPN sequentially during a program operation.

The row decoder 13 may provide a program voltage with an increasing level as the first to N-th program loops LP1 to LPN progress to the selected word line. The level of the seventh_1 program voltage Vpgm7′ applied to the N-th program loop LPN may be higher than the level of the seventh program voltage Vpgm7 applied to the (N−1)-th program loop LP(N−1). The level of the seventh_1 program voltage Vpgm7′ applied to the N-th program loop LPN may be higher than the level of the first program voltage Vpgm1 applied to the first program loop LP1.

As the first to N-th program loops LP1 to LPN progress, the 0-th threshold voltage distribution 800 for the memory cells with the erase status E may be sequentially moved toward the first threshold voltage distribution 810 for the memory cells with the first status P1 to the seventh threshold voltage distribution 870 for the memory cells with the seventh status P7.

The memory cells connected to the selected word line may have sequentially the first to seventh status P1 to P7 from the erase status E through the first to N-th program loops LP1 to LPN. Whether the first to seventh status P1 to P7 passes (e.g., passes verification) may be checked by the first to seventh verify voltages Vvfy1 to Vvfy7.

During the first program loop LP1, the row decoder 13 may apply the first program voltage Vpgm1 and the first verify voltage Vvfy1 to the selected word line. With the application of the first verify voltage Vvfy1, the page buffer circuit 14 may perform the first pre-charge operation.

During the first program loop LP1, the 0-th threshold voltage distribution 800 for the memory cells with erase status E may be raised to the intermediate threshold voltage distribution 805. The page buffer circuit 14 may sense an on-cell region OC and an off-cell region FC of the intermediate threshold voltage distribution 805 based on the first verify voltage Vvfy1. According to an embodiment, the page buffer circuit 14 may temporarily store the off-cell region FC.

According to an embodiment, the control logic 12 may count the off-cell region FC temporarily stored and check whether the first status P1 passes (e.g., passes verification) based on the count value. According to an embodiment, the control logic 12 may check the failure of the first status P1 based on the count value for the off-cell region FC.

The first program loop LP1 may correspond to the steps (S110 to S125) of FIG. 6.

Next, during the (k−1)-th program loop LP(k−1), the row decoder 13 may apply the third program voltage Vpgm3 to the selected word line and apply the fourth verify voltage Vvfy4 and the third verify voltage Vvfy3. According to an embodiment, along with the application of the fourth verify voltage Vvfy4, the page buffer circuit 14 may perform the first pre-charge operation. According to an embodiment, along with the application of the third verify voltage Vvfy3, the page buffer circuit 14 may perform the first pre-charge operation.

During the (k−1)-th program loop LP(k−1), the second threshold voltage distribution 820 for the memory cells having the second status P2 may be raised to the threshold voltage distribution for the memory cells with the third status P3 or the threshold voltage distribution for the memory cells with the fourth status P4.

The control logic 12 may check whether the third status P3 passes (e.g., passes verification) based on the third verify voltage Vvfy3.

The (k−1)-th program loop LP(k−1) may correspond to the steps (S110 to S125) of FIG. 6.

During the k-th program loop LPk, the row decoder 13 may apply a third_1 program voltage Vpgm3′ to the selected word line and apply the fourth verify voltage Vvfy4 and the third verify voltage Vvfy3. According to an embodiment, along with the application of the fourth verify voltage Vvfy4, the page buffer circuit 14 may perform the first pre-charge operation. According to an embodiment, along with the application of the third verify voltage Vvfy3, the page buffer circuit 14 may perform the first pre-charge operation.

During the k-th program loop LPk, the threshold voltage distribution for the memory cells may be raised to the threshold voltage distribution for the memory cells with the third status P3 or the threshold voltage distribution for the memory cells with the fourth status P4.

The control logic 12 may check whether the third status P3 passes (e.g., passes verification) based on the third verify voltage Vvfy3.

The k-th program loop LPk may correspond to the steps (S110 to S125) of FIG. 6.

During the (N−1)-th program loop LP(N−1), the row decoder 13 may apply the seventh program voltage Vpgm7 and the seventh verify voltage Vvfy7 to the selected word line. According to an embodiment, along with the application of the seventh verify voltage Vvfy7, the page buffer circuit 14 may perform the second pre-charge operation.

During the (N−1)-th program loop LP(N−1), the threshold voltage distribution for the memory cells may be raised to the seventh threshold voltage distribution 870 for the memory cells with the seventh status P7.

The control logic 12 may check whether the seventh status P7 passes (e.g., passes verification) based on the seventh verify voltage Vvfy7.

The (N−1)-th program loop LP(N−1) may correspond to the steps (S165 to S180) of FIG. 6.

During the N-th program loop LPN, the row decoder 13 may apply the seventh_1 program voltage Vpgm7′ and the seventh verify voltage Vvfy7 to the selected word line. According to an embodiment, along with the application of the seventh verify voltage Vvfy7, the page buffer circuit 14 may perform the second pre-charge operation.

During the N-th program loop LPN, the threshold voltage distribution for memory cells may be raised to the seventh threshold voltage distribution 870 for the memory cells with the seventh status P7.

The control logic 12 may check whether the seventh status P7 passes (e.g., passes verification) based on seventh verify voltage Vvfy7. According to an embodiment, during the N-th program loop LPN, the control logic 12 may check whether the seventh status P7 passes (e.g., passes verification) based on seventh verify voltage Vvfy7.

The N-th program loop LPN may correspond to the steps (S165 to S190) of FIG. 6.

The size of the pulses and the intervals between the pulses shown in FIG. 7 are only for better understanding and ease of the description and may not be to scale. The size of the threshold voltage distribution and the interval between the threshold voltage distributions shown in FIG. 8 are only for better understanding and ease of the description and may not be matched to a scale.

FIG. 9 to FIG. 12 are views to explain a first pre-charge operation according to an embodiment.

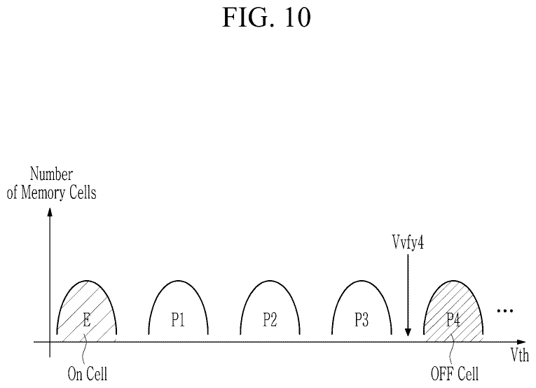

Referring to FIG. 1, FIG. 4, FIG. 5, and FIG. 9 to FIG. 10, for example, the page buffer PB may perform the first pre-charge operation among the verify operations that apply the fourth verify voltage Vvfy4 to verify the fourth status P4.

In the first pre-charge operation, the control logic 12 may control the page buffer PB so that the central significant bit data CSB and the least significant bit data LSB may be dumped into the sensing latch SL based on a status table STa.

The pre-charge circuit PC may apply the pre-charge voltage Vvp to the bit line BL based on whether the central significant bit data CSB and the least significant bit data LSB dumped in the first pre-charge operation are logic low. According to an embodiment, the pre-charge circuit PC may provide the pre-charge voltage Vvp to the memory cell having the fourth status P4 as the target program status through the bit line BL based on the least significant bit data LSB of logic low and the central significant bit data CSB of logic low.

According to an embodiment, the pre-charge circuit PC, based on the central significant bit data CSB of logic low and the least significant bit data LSB of logic low, may provide the pre-charge voltage Vvp to the memory cell having the erase status E as the target program status through the bit line BL. The pre-charge voltage Vvp may be provided to the memory cell with the fourth status P4 as the target program status and the memory cell with the erase status E as the target program status.

The memory cells where the first pre-charge operation is performed and having the fourth status P4 may be sensed as the off-cells through the fourth verify voltage Vvfy4. The memory cells where the first pre-charge operation is performed and having the erase status E may be sensed as the on-cells through the fourth verify voltage Vvfy4.

The pre-charge circuit PC may together apply a specific level of the pre-charge voltage Vvp for the memory cell of the fourth status P4, which is subject to the verification, and the memory cell of the erase status E, which is a part of the lower level status than the fourth status P4.

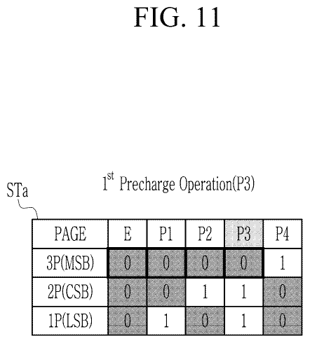

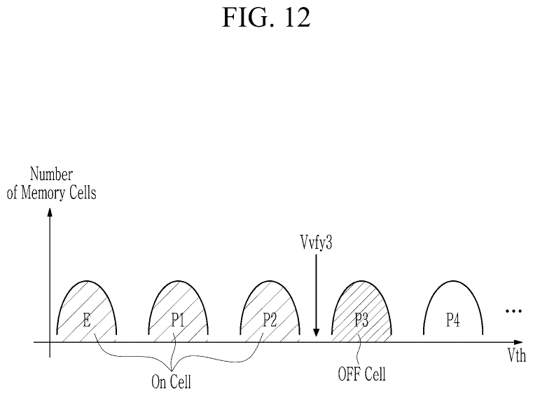

Additionally, referring to FIG. 11 and FIG. 12, for example, the page buffer PB may perform the first pre-charge operation among the verify operations that apply the third verify voltage Vvfy3 to verify the third status P3. In the first pre-charge operation, the control logic 12, based on the status table STa, may control the page buffer PB so that the most significant bit data MSB is dumped to the sensing latch SL.

The pre-charge circuit PC may apply the pre-charge voltage Vvp to the bit line BL based on whether the most significant bit data MSB dumped in the first pre-charge operation is logic low. According to an embodiment, the pre-charge circuit PC, based on the most significant bit data MSB of logic low, may provide together the pre-charge voltage Vvp to the memory cell having the erase status E and the first to third status P1-P3 as the target program status through the bit line BL.

The memory cells where the first pre-charge operation is performed and having the third status P3 may be sensed as the off-cells through the third verify voltage Vvfy3. The memory cells in which the first pre-charge operation is performed and having one of the erase status E and the first to second status P1 and P2 may be sensed as the on-cells through the third verify voltage Vvfy3.

The pre-charge circuit The PC may apply a specific level of pre-charge voltage Vvp together for the memory cell of the third status P3 to be verified and the memory cell with the lower level status E, P1, and P2 than the third status P3.

In the first pre-charge operation, the page buffer circuit 14 may select the program status to which the pre-charge voltage is applied with only logic low of some of the bit data MSB, CSB, and LSB corresponding to the target program status as an AND condition. In addition to the specific target program status, the pre-charge voltage Vvp may be applied together to the memory cells with the selected program status, and the number of data transfer operations within the page buffer PB to select the specific target program status may be reduced.

The page buffer PB according to the embodiment, by performing the first pre-charge operation for the memory cell having the first to fourth status P1 to P4 of the relatively lower level status, may reduce the power-efficiency degradation due to the on-cell operation of the memory cell with the lower level status than the target program status in the verify operation.

FIG. 13 to FIG. 14 are views to explain a second pre-charge operation according to an embodiment.

Referring to FIG. 1, FIG. 4, FIG. 5, and FIG. 13 to FIG. 14, for example, the page buffer PB may perform the second pre-charge operation among the verify operations that apply the sixth verify voltage Vvfy6 to verify the sixth status P6.

Before performing the second pre-charge operation, the latch circuit in the page buffer PB, which stores the bit data MSB, CSB, and LSB corresponding to the first to the fourth status P1 to P4, may be cleared. The bit data MSB, CSB, and LSB on which the clear operation was performed may all store logic low. The page buffer PB on which the clear operation was performed may store the bit data MSB, CSB, and LSB corresponding to the erase status E.

In the second pre-charge operation, the control logic 12 may control the page buffer PB so that central significant bit data CSB and the least significant bit data LSB may be dumped into the sensing latch SL based on the status table STb.

The pre-charge circuit PC may apply the pre-charge voltage Vvp to the bit line BL based on the central significant bit data CSB of logic high and the least significant bit data LSB of logic low dumped in the second pre-charge operation. According to an embodiment, the pre-charge circuit PC may selectively provide the pre-charge voltage Vvp to the memory cell with the sixth status P6 as the target program status through the bit line BL.

The memory cells on which the second pre-charge operation is performed and having the sixth status P6 may be selectively sensed as off-cells through the sixth verify voltage Vvfy6. The pre-charge circuit PC may selectively apply the pre-charge voltage Vvp only to the memory cell of the sixth status P6 that is subject to the verification.

The page buffer PB may perform the selected second pre-charge operation to the program status for the memory cell having the fifth to seventh status P5 to P7 of the relatively higher level status. The page buffer PB may perform the second pre-charge operation that selectively applies the pre-charge voltage based on the central significant bit data CSB and the least significant bit data LSB assuming the clear operation for the latch circuit that stores the bit data for the lower level status.

Through the second pre-charge operation, the page buffer PB may selectively apply the pre-charge voltage while reducing dumping of the most significant bit data MSB from the cache latch 141 distantly spaced.

The page buffer PB may impede/prevent the power-efficiency from being degraded due to the on-cell operation by selectively applying the pre-charge voltage to the program status for the fifth to seventh status P5 to P7, which are a relatively higher level status.

In the pre-charge operation during the program operation, the non-volatile memory device 10 may perform the first pre-charge operation on the memory cell with the relatively lower level status and the second pre-charge operation on the memory cell with the relatively higher level status. The non-volatile memory device 10 may improve a speed performance and the power-efficiency for the program operation through the first and second pre-charge operations as described above.

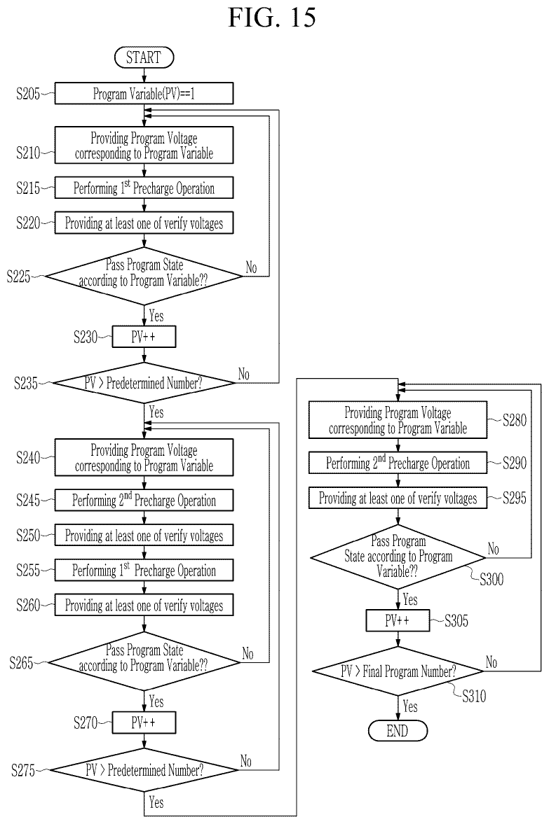

FIG. 15 is a flowchart to explain a program operation method of a non-volatile memory device according to an embodiment.

The steps (S205 to S235) of FIG. 15 and the steps (S105 to S135) of FIG. 6 may respectively correspond to each other, and the steps (S280 to S310) of FIG. 15 and the steps (S165 to S190) of FIG. 6 may respectively correspond to each other. For ease of the explanation, the description of the steps (S205 to S235) and the step (S280 to S310) of FIG. 15 focus on the differences from the explanations of the steps (S105 to S135) and the steps (S165 to S190) in FIG. 6.

Referring to FIG. 1, FIG. 5, FIG. 6, and FIG. 15, if the increased program variable PV in the step (S230) is greater than the predetermined number, the row decoder 13 provides the program voltage Vpgm corresponding to the predetermined program variable PV to the selected word line (S240).

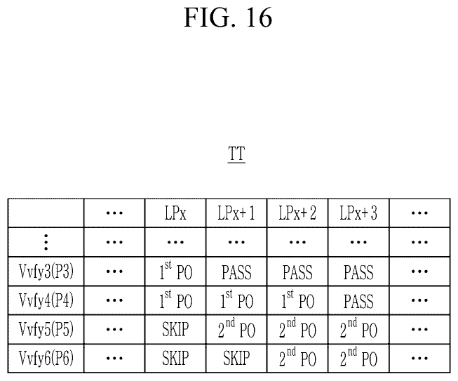

According to an embodiment, the predetermined number may vary. If FIG. 16 is explained as an example, the predetermined number may be ‘3’, but is not limited thereto. The step (S240) may correspond to the step (S210), and the step (S110), and hereinafter, for ease of the explanation, the description of the step (S240) may be replaced with the description of the step (S110) described above.

The page buffer circuit 14 performs the second pre-charge operation (S245).

The step (S245) may correspond to the step (S170)

However, before the second pre-charge operation in the step (S245), a clear operation such as the step (S160) may not be performed on the latch circuit in the page buffer PB corresponding to the passed memory cell.

In the step (S245), the page buffer PB may perform the second pre-charge operation selectively applying the pre-charge voltage based on the most significant bit data MSB, the central significant bit data CSB, and the least significant bit data LSB.

The row decoder 13 provides at least one verify voltage Vvfy to the selected word line (S250).

The step (S250) may correspond to the step (S220) and the step (S120), and hereinafter for ease of explanation, the description of the step (S250) may be replaced with the description of the step (S120) described above.

The page buffer circuit 14 performs the first pre-charge operation (S255).

The step (S255) may correspond to the step (S215) and the step (S115), and hereinafter, for ease of explanation, the description of the step (S255) may be replaced with the description of the step (S115) described above.

The row decoder 13 provides at least one verify voltage Vvfy to the selected word line (S260).

The step (S260) may correspond to the step (S220) and the step (S120), and hereinafter, for ease of explanation, the description of the step (S260) may be replaced with the description of the step (S120) described above.

According to an embodiment, the step (S240) to the step (S260) may be operated with one program loop. In FIG. 15, the step (S245) is shown as preceding the step (S255), but the disclosure is not limited to this order and according to an embodiment the step (S255) may precede the step (S245).

The control logic 12 checks whether the program status corresponding to the program variable PV passes (e.g., passes verification) based on the verify operation (S265).

The step (S265) may correspond to the step (S225) and the step (S125) described above. For ease of explanation, the explanation of the step (S265) is explained mainly on the differences from the explanation of the step (S125).

If the program status corresponding to the program variable PV is not passed, the step (S240) to the step (S260) may be performed repeatedly. According to an embodiment, the step (S240) to the step (S260) may be operated with one program loop.

If the program status corresponding to the program variable PV is passed (e.g., passes verification), the predetermined program variable PV is increased (S270).

The step (S270) may correspond to the step (S230) and the step (S130) described above. For ease of explanation, the description of the step (S270) may be replaced with the description of the step (S130).

The increased program variable PV is compared with the predetermined number (S275).

According to an embodiment, the predetermined number may vary. If FIG. 16 is explained as an example, the predetermined number may be ‘4’, but is not limited thereto. According to an embodiment, if the increased program variable PV is less than or equal to the predetermined number ‘4’, the step (S240) to the step (S270) may be repeated.

According to an embodiment, the comparison operation of the step (S275) may be a step of checking and comparing whether the program status passed immediately before is a predetermined program status.

If the program variable PV increased in the step (S270) is greater than the predetermined number, the row decoder 13 provides the program voltage Vpgm corresponding to the predetermined program variable PV to the selected word line (S280).

Next, in the step (S280) to the step (S310), between the second pre-charge operation of the step (S290), for the latch circuit in the page buffer PB corresponding to the passed memory cell, the clear operation such as the step (S160) may not be performed.

In the step (S290), the page buffer PB may perform the second pre-charge operation of selectively applying the pre-charge voltage based on the most significant bit data MSB, the central significant bit data CSB, and the least significant bit data LSB.

FIG. 16 is a time table for explaining a program operation method of a non-volatile memory device according to an embodiment. Specifically, a time table TT of FIG. 16 may be a time table that illustratively visualizes the program operation method of FIG. 15.

Referring to FIG. 1, FIG. 6, FIG. 15, and FIG. 16, while performing the program operation, the non-volatile memory device 10 may sequentially perform a x-th program loop LP(x), a (x+1)-th program loop LP(x+1), a (x+2)-th program loop LP(x+2), and a (x+3)-th program loop LP(x+3).

The row decoder 13 may apply the third to fourth verify voltage Vvfy3 to Vvfy4 to the selected word line during the x-th program loop LP(x).

According to an embodiment, the row decoder 13 may provide the third program voltage corresponding to the third verify voltage Vvfy3 in the x-th program loop LP(x) to the selected word line. According to an embodiment, the row decoder 13 may sequentially provide the fourth verify voltage Vvfy4 and the third verify voltage Vvfy3 to the selected word line.

According to an embodiment, along with the provision of the third to fourth verify voltage Vvfy3 to Vvfy4 as described above, the page buffer 14 may perform the first pre-charge operation on the memory cell that is the target of the verify operation. According to an embodiment, the page buffer circuit 14, based on whether some of the dumped bit data among the most significant bit data MSB, the central significant bit data CSB, and the least significant bit data LSB is logic low, may apply the pre-charge voltage of a specific level together for the memory cells with the third to fourth status P3 to P4 and the memory cells with the lower level status than the third to fourth status P3 to P4.

According to an embodiment, the control logic 12 may check and determine whether the third status P3 is passed (e.g., passes verification) based on the third verify voltage Vvfy3 in the x-th program loop LP(x).

According to an embodiment, the step (S210) to the step (S235) may be performed in the x-th program loop LP(x).

According to an embodiment, the control logic 12 may check and determine the pass for the third status P3 based on the third verify voltage Vvfy3 in the x-th program loop LP(x). Next, the row decoder 13 may apply the fourth to fifth verify voltage Vvfy4 to Vvfy5 to the selected word line during the (x+1)-th program loop LP(x+1).

According to an embodiment, the row decoder 13 may provide the fourth program voltage corresponding to the fourth verify voltage Vvfy4 in the (x+1)-th program loop LP(x+1) to the selected word line. According to an embodiment, the row decoder 13 may sequentially provide the fifth verify voltage Vvfy5 and the fourth verify voltage Vvfy4 to the selected word line.

According to an embodiment, along with the provision of the fourth to fifth verify voltage Vvfy4 to Vvfy5 as above, the page buffer 14 may perform the pre-charge operation in different ways depending on the program status of the memory cell that is the target of the verify operation.

According to an embodiment, along with the provision of the fifth verify voltage Vvfy5, the page buffer 14 may perform the second pre-charge operation that selectively provides the specific level of the pre-charge voltage to the memory cell that is the target of the verify operation.

According to an embodiment, the page buffer 14 may apply the specific level of the pre-charge voltage to the memory cell having the fifth status P5 based on the dumped most significant bit data MSB, central significant bit data CSB, and least significant bit data LSB.

According to an embodiment, along with the provision of the fourth verify voltage Vvfy4, the page buffer 14 may perform the first pre-charge operation on the memory cell that is the target of the verify operation.

According to an embodiment, the page buffer circuit 14, based on whether some of the dumped bit data among the most significant bit data MSB, the central significant bit data CSB, and the least significant bit data LSB is logic low, may apply the pre-charge voltage of the specific level together to the memory cell with the fourth status P4 and the memory cell with the level status lower than the fourth status P4.

According to an embodiment, the control logic 12 may check and determine whether the fourth status P4 is passed (e.g., passes verification) based on the fourth verify voltage Vvfy4 in the (x+1)-th program loop LP(x+1).

According to an embodiment, in the (x+1)-th program loop LP(x+1), the step (S240) to the step (S275) may be performed.

According to an embodiment, the control logic 12 may check and determine a failure for the fourth status P4 based on the fourth verify voltage Vvfy4 in in the (x+1)-th program loop LP(x+1). Next, the row decoder 13 may apply the fourth to sixth verify voltages Vvfy4 to Vvfy6 to the selected word line during the (x+2)-th program loop LP(x+2).

According to an embodiment, the row decoder 13 may provide the fourth program voltage corresponding to the fourth verify voltage Vvfy4 to the selected word line in the (x+2)-th program loop LP(x+2). According to an embodiment, the row decoder 13 may sequentially provide the sixth verify voltage Vvfy6, the fifth verify voltage Vvfy5, and the fourth verify voltage Vvfy4 to the selected word line.

According to an embodiment, along with the provision of the fourth to sixth verify voltages Vvfy4 to Vvfy6 as described above, the page buffer 14 may perform the pre-charge operation in different ways depending on the program status of the memory cell that is the target of the verify operation.

According to an embodiment, along with the provision of the fifth and sixth verify voltages Vvfy5 to Vvfy6, the page buffer 14 may perform the second pre-charge operation of selectively providing the specific level of the pre-charge voltage to the memory cell that is the target of the verify operation.

According to an embodiment, the page buffer 14 may apply the specific level of the pre-charge voltage to the memory cell with the fifth status P5 and the sixth status P6, based on the dumped most significant bit data MSB, central significant bit data CSB, and least significant bit data LSB.

According to an embodiment, along with the provision of the fourth verify voltage Vvfy4, the page buffer 14 may perform the first pre-charge operation on the memory cell that is the target of the verify operation.

According to an embodiment, the page buffer circuit 14, based on whether some of the dumped bit data among the most significant bit data MSB, the central significant bit data CSB, and the least significant bit data LSB is logic low, may together apply the specific level of the pre-charge voltage for the memory cell having the fourth status P4 and the memory cell with the lower level status than the fourth status P4.

According to an embodiment, the control logic 12 may check and determine whether the fourth status P4 is passed (e.g., passes verification) based on the fourth verify voltage Vvfy4 in the (x+2)-th program loop LP(x+2).

According to an embodiment, the step (S240) to the step (S275) may be performed in the (x+2)-th program loop LP(x+2).

According to an embodiment, the control logic 12 may check and determine the pass for the fourth status P4 based on the fourth verify voltage Vvfy4 in the (x+2)-th program loop LP(x+2). Next, the row decoder 13 may apply the fifth to sixth verify voltages Vvfy5 to Vvfy6 to the selected word line during the (x+3)-th program loop LP(x+3).

According to an embodiment, the row decoder 13 may provide the fifth program voltage corresponding to the fifth verify voltage Vvfy5 in the (x+3)-th program loop LP(x+3) to the selected word line. According to an embodiment, the row decoder 13 may sequentially provide the sixth verify voltage Vvfy6 and the fifth verify voltage Vvfy5 to the selected word line.

According to an embodiment, along with the provision of the fifth and sixth verify voltages Vvfy5 and Vvfy6, the page buffer 14 may perform the second pre-charge operation of selectively providing the specific level of the pre-charge voltage to the memory cell that is the target of the verify operation.

According to an embodiment, the page buffer 14 may apply the specific level of the pre-charge voltage to the memory cell with the fifth status P5 and the sixth status P6, based on the dumped most significant bit data MSB, central significant bit data CSB, and least significant bit data LSB.

According to an embodiment, in the (x+3)-th program loop LP(x+3), the step (S280) to the step (S310) may be performed.

According to an embodiment, through the program operation of FIG. 15 and FIG. 16, the non-volatile memory device 10 may not perform a clear operation on the latch circuit in the page buffer corresponding to the passed program status. According to an embodiment, the non-volatile memory device 10 may specify the type of the pre-charge operation for the program status, regardless of whether the program loop is performed and whether the specific program status is passed (e.g., passes verification).

In FIG. 16, with reference to the fourth and fifth status P4 and P5, it is distinguished that the first pre-charge operation may be performed on the memory cell with the lower level status and the second pre-charge operation may be performed on the memory cell with the higher level status, but the disclosure is not limited to the reference example, and the distinguish reference according to each embodiment may be changed.

According to an embodiment, the non-volatile memory device 10 may change the reference for performing the pre-charge operation, and the degree of the improvement in speed performance and electric power performance for the program operation may change.

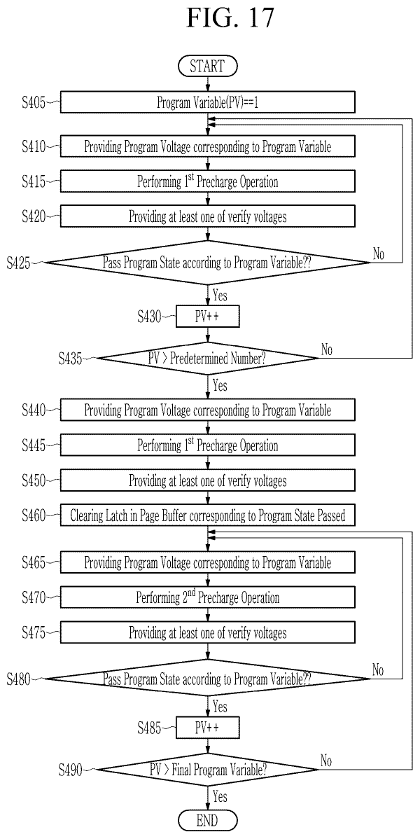

FIG. 17 is a flowchart to explain a program operation method of a non-volatile memory device according to an embodiment.

The step (S405) to the step (S435) of FIG. 17 and the step (S105) to the step (S135) of FIG. 6 may respectively correspond to each other, the step (S460) to the step (S490) of FIG. 17 and the step (S160) to the step (S190) of FIG. 6 may respectively correspond to each other. For ease of explanation, the description of the step (S405) to the step (S435), and the step (S460) to the step (S490) in FIG. 17 may focus on differences from the explanation of the step (S105) to the step (S135), and the step (S160) to the step (S190) in FIG.

Referring to FIG. 1, FIG. 5, FIG. 6, and FIG. 17, if the program variable PV increased in the step (S430) is greater than a predetermined number, the row decoder 13 provides the program voltage Vpgm corresponding to the predetermined program variable PV to the selected word line (S440).

According to an embodiment, if the memory cell is a TLC, the predetermined number may be ‘4’. The step (S440) may correspond to the step (S410) and the step (S110), and hereinafter, for ease of explanation, the description of the step (S440) may be replaced with the description of the step (S110) described above.

The page buffer circuit 14 performs the first pre-charge operation (S445).

The step (S445) may correspond to the step (S415) and the step (S115), and hereinafter, for ease of explanation, the description of the step (S445) may be replaced with the description of the step (S115) described above.

The row decoder 13 provides at least one verify voltage Vvfy to the selected word line (S450).

The step (S450) may correspond to the step (S420) and the step (S120), and hereinafter, for ease of explanation, the description of the step (S450) may be replaced with the description of the step (S120) described above.

According to an embodiment, the step (S440) to the step (S450) may be operated with one program loop.

After performing the program loop corresponding to the step (S440) to the step (S450), the control logic 12 clears the latch circuit in the page buffer PB corresponding to the passed program status (S460).

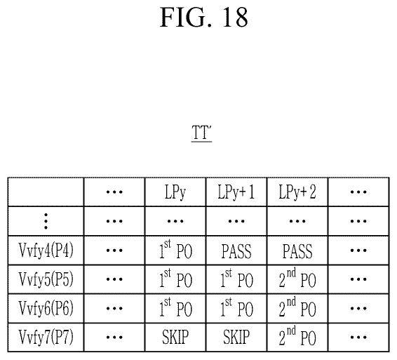

FIG. 18 is a time table for explaining a program operation method of a non-volatile memory device according to an embodiment. A time table TT′ of FIG. 18 specifically may be a time table that illustratively visualizes the program operation method in FIG. 17.

Referring to FIG. 1, FIG. 6, FIG. 17, and FIG. 18, the non-volatile memory device 10 may sequentially perform the y-th program loop LPy, the (y+1) program loop LP(y+1), and the (y+2) program loop LP(y+2) while performing a program operation.

The row decoder 13 may apply the fourth to sixth verify voltages Vvfy4 to Vvfy6 to the selected word line during the y-th program loop LPy.

According to an embodiment, the row decoder 13 may provide the fourth program voltage corresponding to the fourth verify voltage Vvfy4 in the y-th program loop LPy to the selected word line. According to an embodiment, the row decoder 13 may sequentially provide the sixth verify voltage Vvfy6, the fifth verify voltage Vvfy5, and the fourth verify voltage Vvfy4 to the selected word line.

According to an embodiment, along with the provision of the fourth to sixth verify voltages Vvfy4 to Vvfy6 as described above, the page buffer 14 may perform the first pre-charge operation on the memory cell that is the target of the verify operation. According to an embodiment, the page buffer circuit 14, based on whether some of the dumped bit data among the most significant bit data MSB, the central significant bit data CSB, and the least significant bit data LSB is logic low, may together apply the pre-charge voltage of a specific level to the memory cell with the fourth to sixth status P4 to P6 and the memory cell with the level status lower than the fourth to sixth status P4 to P6.

According to an embodiment, the control logic 12 may check and determine whether the fourth status P4 passes (e.g., passes verification) based on the fourth verify voltage Vvfy4 in the y-th program loop LPy.

According to an embodiment, the step (S410) to the step (S435) may be performed in the y-th program loop LPy.

According to an embodiment, the control logic 12 may check and determine the pass for the fourth status P4 based on the fourth verify voltage Vvfy4 in the y-th program loop LPy. Next, the row decoder 13 may apply the fifth to sixth verify voltages Vvfy5 to Vvfy6 to the selected word line during the (y+1) program loop LP(y+1).

According to an embodiment, the row decoder 13 may provide the fifth program voltage corresponding to the fifth verify voltage Vvfy5 in the (y+1) program loop LP(y+1) to the selected word line. According to an embodiment, row decoder 13 can sequentially provide sixth verify voltage Vvfy6), and fifth verify voltage Vvfy5 to the selected word line.

According to an embodiment, along with the provision of the fifth to sixth verify voltages Vvfy5 to Vvfy6 as described above, the page buffer 14 may perform the first pre-charge operation on the memory cell that is the target of the verify operation. According to an embodiment, the page buffer circuit 14, based on whether some of the dumped bit data among the most significant bit data MSB, the central significant bit data CSB, and the least significant bit data LSB is logic low, may apply together the pre-charge voltage of a specific level to the memory cell with the fifth to sixth status P5 and P6 and the memory cell with a level status lower than the fifth to sixth status P5 and P6.

According to an embodiment, the control logic 12 may clear the latch circuit in the page buffer PB that stores the bit data corresponding to the program status less than the fourth status P4 passed in the (y+1) program loop LP(y+1).

According to an embodiment, the step (S440) to the step (S460) may be performed in the (y+1) program loop LP(y+1).

The row decoder 13 may apply the fifth to seventh verify voltage Vvfy5 to Vvfy7 to the selected word line during the (y+2) program loop LP(y+2).

According to an embodiment, the row decoder 13 may provide the fifth program voltage corresponding to the fifth verify voltage Vvfy5 in the (y+2) program loop LP(y+2) to the selected word line. According to an embodiment, the row decoder 13 may sequentially provide the seventh verify voltage Vvfy7, the sixth verify voltage Vvfy6, and the fifth verify voltage Vvfy5 to the selected word line.

According to an embodiment, along with the provision of the fifth to seventh verify voltages Vvfy5 to Vvfy7 as above, the page buffer 14 may perform a second pre-charge operation that selectively provides the pre-charge voltage of a specific level to the memory cell that is the target of the verify operation.

According to an embodiment, the control logic 12 may check whether the fifth status P5 passes (e.g., passes verification) based on the fifth verify voltage Vvfy5 in the (y+2) program loop LP(y+2).

According to an embodiment, the step (S465) to the step (S490) may be performed in the (y+2) program loop LP(y+2).

Through the program operation of FIG. 17 and FIG. 18, similar to the read operation environment, the non-volatile memory device 10 may perform the verify operation on the fifth status P5 while performing the first pre-charge operation for the memory cell with the fifth status P5 after confirming the pass of the fourth status P4. The non-volatile memory device 10 according to the embodiment, similar to the read environment through the program operation of FIG. 17 and FIG. 18, may improve the reliability of the verify operation by performing the verify operation.

Through the program operation of FIG. 17 and FIG. 18, the non-volatile memory device 10 may improve the speed performance and the power-efficiency for the program operation while easily controlling the program operation by using the first pre-charge operation and the second pre-charge operation with the program loop as a reference.

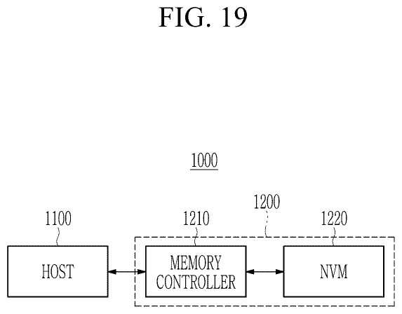

FIG. 19 is a block diagram showing a user device including a non-volatile memory device according to an embodiment. Referring to FIG. 19, the user device 1000 may include a host 1100 and a data storage device 1200.

The host 1100 may be configured to control the data storage device 1200. For example, the host 1100 may include one or more portable electronic devices such as a personal/portable computer, a personal digital assistant (PDA), a portable media player (PMP), an MP3 player, etc.

The host 1100 and the data storage device 1200 may be connected by a standardized interface such as USB, SCSI, ESDI, SATA, SAS, PCI express, or IDE interface. However, the interface method to connect the host 1100 and the data storage device 1200 is not limited thereto.

The data storage device 1200 may include a memory controller 1210 and a non-volatile memory device 1220. The memory controller 1210 may control the program/read/erase operations of the non-volatile memory device 1220 in response to a request from the host 1100.

The non-volatile memory device 1220 may include a plurality of non-volatile memory chips. The non-volatile memory device 1220, as described in FIG. 1 to FIG. 18, may perform the program operation while performing differently the first pre-charge operation and the second pre-charge operation by varying the target program status and the operation time within the program operation. The non-volatile memory device 1220, through the operation in FIG. 1 to FIG. 18, may perform the program operations with the improved performance and power-efficiency.

The data storage device 1200 may be configured as a semiconductor disk (a solid state disk; SSD) device. However, this is just an example, the data storage device 1200 may be integrated into a single semiconductor device, and may be composed of a PC card (personal computer memory card international association; PCMCIA), a compact flash card (CF), a smart media card (SM, SMC), a memory stick, a multimedia card (MMC, RS-MMC, MMC-micro), a SD card (SD, mini SD, microSD, SDHC), a universal flash memory device (UFS), etc.

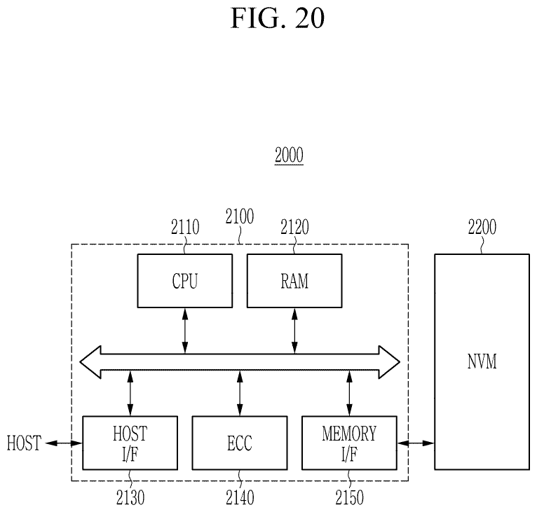

FIG. 20 is a block diagram showing an application example of a memory system including a non-volatile memory device according to an embodiment.

Referring to FIG. 20, a memory system 2000 may include a memory controller 2100 and a non-volatile memory device 2200.

The memory controller 2100 may control the program/read/erase operations of the non-volatile memory device 2200 in response to a request from the host 1100 (FIG. 19). The memory controller 2100 may include a CPU 2110, a RAM 2120, a host interface 2130, an error correction block 2140, and a memory interface 2150.

The CPU 2110 may control all operations of the memory controller 2100. The RAM 2120 may be used as a working memory for the CPU 2110. The host interface 2130 may exchange data by interfacing with the host connected to the memory system 2000.

The error correction block 2140 may detect and correct errors in the data read from the non-volatile memory device 2200. The memory interface 2150 may exchange the data by interfacing with the non-volatile memory device 2200.

The non-volatile memory device 2200 may be composed of a plurality of non-volatile memory chips. The non-volatile memory device 2200, as described in FIG. 1 to FIG. 18, may perform the program operation while performing the first pre-charge operation and the second pre-charge operation differently by varying the target program status and the operation time within the program operation. The non-volatile memory device 2200, through the operation in FIG. 1 to FIG.18, may perform the program operation with improved performance and power-efficiency.

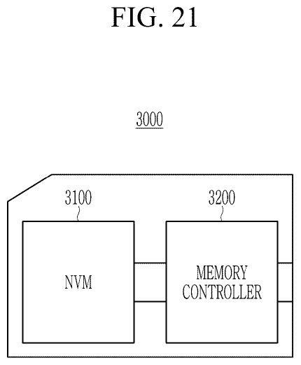

FIG. 21 is a block diagram showing a data storage device including a non-volatile memory device according to an embodiment.

Referring to FIG. 21, the data storage device 3000 may include a non-volatile memory device 3100 and a memory controller 3200.

The non-volatile memory device 3100, as described in FIG. 1 to FIG. 18, may perform the program operation while performing the first pre-charge operation and the second pre-charge operation differently by varying the target program status and the operation time within the program operation. The non-volatile memory device 3100, through the operation in FIG. 1 to FIG.18, may perform the program operation with improved performance and power-efficiency.

The memory controller 3200 may control the program/read/erase operation of the non-volatile memory device 3100 in response to requests from the outside (e.g., from outside of the non-volatile memory device 3100).

The data storage device 3000 may be configured as a memory card device, an SSD device, a multimedia card device, a SD device, a memory stick device, a hard disk drive device, a hybrid drive device, or a universal serial bus flash device. For example, the data storage device 3000 may configure a card to use a user device such as a digital camera, personal computer, etc.

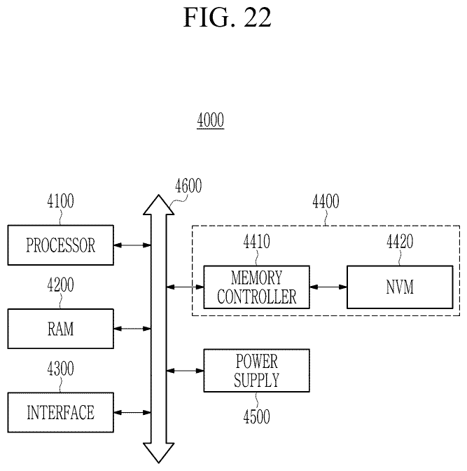

FIG. 22 is a block diagram showing a computing system including a non-volatile memory device according to an embodiment.

Referring to FIG. 22, a computer system 4000 may include a processor 4100, a RAM 4200, an interface device 4300, a memory system 4400, a power supply 4500, and a bus 4600.

The processor 4100, the RAM 4200, the interface device 4300, the memory system 4400, and the power supply 4500 may be coupled to each other through the bus 4600. The bus 4600 corresponds to a path through which data may be moved.

The processor 4100 may include at least one of a microprocessor, a digital signal processor, a microcontroller, and a logic device capable of performing similar functions thereto.

The RAM 4200 may be used as a working memory to improve the performance of processor 4100. The interface device 4300 may perform a function of transmitting data to a communication network or receiving data from a communication network.

The interface device 4300 may be wired or wireless. For example, the interface device 4300 may include an antenna or a wireless transceiver.

The memory system 4400 may store data and/or instructions, etc. The memory system 4400 may include a memory controller 4410 and a non-volatile memory device 4420.

The memory controller 4410 may control the program/read/erase operation of the non-volatile memory device 4420. The non-volatile memory device 4420 may include a plurality of non-volatile memory chips. The non-volatile memory device 4420, as described in FIG. 1 to FIG. 18, may perform the program operation while performing the first pre-charge operation and the second pre-charge operation differently by varying the target program status and the operation time within the program operation. The non-volatile memory device 4420, through the operation in FIG. 1 to FIG. 18, may perform the program operation with improved performance and power-efficiency.

The power supply 4500 may supply an operation power to the processor 4100, the RAM 4200, the interface device 4300, and the memory system 4400.

The computing system 4000 may be applied to a personal digital assistant (PDA,), a portable computer, a web tablet, a wireless phone, a mobile phone, a digital music player, a memory card, or all electronic products that can transmit and/or receive an information in a wireless environment.

While this disclosure has been described in connection with what is presently considered to be practical example embodiments, it is to be understood that the disclosure is not limited to the disclosed embodiments, but, on the contrary, is intended to cover various modifications and equivalent arrangements included within the scope of the appended claims.

What is claimed is:

1. A non-volatile memory device comprising:
a memory cell array including a first memory cell connected to a first bit line and having a first program status, a second memory cell connected to a second bit line that is different from the first bit line and having a second program status that is a higher level status than the first program status, and a third memory cell connected to a third bit line that is different from the first and second bit lines and having a third program status that is a higher level status than the first program status and the second program status; and
a page buffer configured to apply a pre-charge voltage to the first and second bit lines in a first verify operation for the second program status, and apply the pre-charge voltage to the third bit line in a second verify operation for the third program status.

2. The non-volatile memory device of claim 1, wherein:
the memory cell array further includes a fourth memory cell connected to a fourth bit line that is different from the first to third bit lines, and having a fourth program status that is a lower level status than the second program status and is different from the first program status, and
the page buffer is configured to apply the pre-charge voltage to the first bit line, the second bit line, and the fourth bit line in the first verify operation.

3. The non-volatile memory device of claim 1, wherein:
each of the first, second, and third memory cells comprises a triple level cell (TLC),
the TLC has one of an erase status or a first status to a seventh status,
status increases sequentially from the first status to the seventh status, and
the third program status is one of the fifth status, the sixth status, or the seventh status.

4. The non-volatile memory device of claim 3, wherein:
the second program status is one of the first status, the second status, the third status, or the fourth status.

5. The non-volatile memory device of claim 1, wherein:
the page buffer includes a first page buffer connected to the first bit line, and a second page buffer connected to the second bit line,
the first page buffer includes a first data latch configured to store first data written to the first memory cell, a first cache latch configured to provide the first data to the first data latch, and a first pre-charge circuit configured to apply the pre-charge voltage to the first bit line based on at least a part of a plurality of first bit data stored in the first data latch and the first cache latch in the first verify operation, and
the second page buffer includes a second data latch configured to store second data written in the second memory cell, a second cache latch configured to provide the second data to the second data latch, and a second pre-charge circuit configured to apply the pre-charge voltage to the second bit line based on at least a part of a plurality of second bit data stored in the second data latch and the second cache latch in the first verify operation.

6. The non-volatile memory device of claim 5, wherein:
at least part of the plurality of first bit data is dumped into a first sensing latch,
at least part of the plurality of second bit data is dumped into a second sensing latch,
the first pre-charge circuit is configured to apply the pre-charge voltage to the first bit line based on at least a portion of the plurality of first bit data dumped in the first sensing latch, and
the second pre-charge circuit is configured to apply the pre-charge voltage to the second bit line based on at least a portion of the plurality of second bit data dumped into the second sensing latch.

7. The non-volatile memory device of claim 6, wherein:
the page buffer further includes a third page buffer connected to the third bit line, and
the third page buffer includes a third data latch configured to store the third data written in the third memory cell, a third cache latch configured to provide the third data to the third data latch, and a third pre-charge circuit configured to apply the pre-charge voltage to the third bit line based on a plurality of third bit data latched to the third data latch in the second verify operation.

8. The non-volatile memory device of claim 7, wherein:
in the second verify operation,
the plurality of first bit data stored in the first data latch and the first cache latch are cleared, and the plurality of second bit data stored in the second data latch and the second cache latch are cleared.

9. The non-volatile memory device of claim 7, wherein:
the plurality of third bit data is dumped into a third sensing latch, and
the third pre-charge circuit is configured to apply the pre-charge voltage to the third bit line based on the plurality of third bit data dumped into the third sensing latch.

10. The non-volatile memory device of claim 1, wherein:
in the first verify operation,
the first memory cell is sensed as an on-cell, and the second memory cell is sensed as an off-cell.

11. The non-volatile memory device of claim 10, wherein:
in the second verify operation,
the third memory cell is sensed as an off-cell.

12. The non-volatile memory device of claim 11, wherein:
in the second verify operation,
the page buffer is configured to apply the pre-charge voltage to the third bit line and not to apply the pre-charge voltage to the first and second bit lines.

13. A non-volatile memory device comprising:
a memory cell array including a first memory cell having a first program status and connected to a first bit line during a plurality of program loops including different first and second program loops, and a second memory cell having a second program status that is a higher level status than the first program status and connected to a second bit line different from the first bit line during the plurality of program loops; and
a page buffer configured to apply a pre-charge voltage to the first and second bit lines in a first verify operation for the second program status during the first program loop and apply the pre-charge voltage to the second bit line in a second verify operation for the second program status during the second program loop.

14. The non-volatile memory device of claim 13, wherein:
during the first program loop, the first program status passes verification.

15. The non-volatile memory device of claim 14, wherein:
the memory cell array further includes a third memory cell having a third program status that is a higher level status than the second program status and connected to a third bit line that is different from the first and second bit lines during the plurality of program loops,
during the first program loop, in a third verify operation for the third program status, the page buffer is configured to apply the pre-charge voltage to the third bit line and apply the pre-charge voltage to at least one of the first and second bit lines.

16. The non-volatile memory device of claim 15, wherein:
in a fourth verify operation for the third program status during the second program loop, the page buffer is configured to apply the pre-charge voltage to the third bit line and not to apply the pre-charge voltage to the first and second bit lines.

17. An operation method of a non-volatile memory device, the operation method comprising:
applying a first program voltage during a first program loop;
providing, during the first program loop, a pre-charge voltage to a first bit line connected to a first memory cell having a first program status, and a second bit line connected to a second memory cell with a second program status that is a higher level status than the first program status and different from the first bit line;
checking whether the first program status passes verification;
comparing the first program status with a predetermined program status;
applying a second program voltage different from the first program voltage during a second program loop after the comparison; and
providing the pre-charge voltage to a third bit line connected to a third memory cell having a third program status that is a level higher than the second program status during the second program loop.

18. The operation method of the non-volatile memory device of claim 17, further comprising:
providing the pre-charge voltage to the first and second bit lines during the second program loop.

19. The operation method of the non-volatile memory device of claim 17, further comprising:
clearing a data latch of a first page buffer connected to the first bit line in response to a result of the comparison between the first program status and the predetermined program status.

20. The operation method of the non-volatile memory device of claim 19, wherein providing the pre-charge voltage to the third bit line includes:
dumping first bit data stored in a data latch in a third page buffer connected to the third bit line, and
not performing a dumping operation on a cache latch in the third page buffer.
